(19) United States
(12) Patent Application Publication
(10) Pub. No.: US 2025/0056912 A1
(43) Pub. Date: Feb. 13, 2025

(54) IMAGING DEVICE

(71) Applicant: Panasonic Intellectual Property Management Co., Ltd., Osaka (JP)

(72) Inventor: YOSHIHIRO SATO, Osaka (JP)

(21) Appl. No.: 18/931,126

(22) Filed: Oct. 30, 2024

Related U.S. Application Data
(63) Continuation of application No. PCT/JP2023/014790, filed on Apr. 12, 2023.

(30) Foreign Application Priority Data
May 16, 2022 (JP) 2022-080533

(51) Int. Cl. H01L 27/146; H04N 25/65; H04N 25/77

(52) U.S. Cl. CPC H01L 27/14623; H01L 27/14612; H01L 27/14636; H01L 27/14643; H04N 25/65; H04N 25/77

(57) ABSTRACT

A second cell is less sensitive than a first cell. The first cell includes a first charge accumulator and a first wire. The first charge accumulator accumulates first signal charge and is electrically connected to a first node. The first wire is located within an upper wiring layer and is electrically connected to the first node. The second cell includes a second charge accumulator and a second wire. The second charge accumulator accumulates second signal charge and is electrically connected to a second node. The second wire is located within the upper wiring layer and is electrically connected to the second node. In the upper wiring layer, a shortest distance between the first wire and wires is greater than a shortest distance between the second wire and the wires.

### BACKGROUND

### 1. Technical Field

The present disclosure relates to an imaging device.

### 2. Description of the Related Art

Imaging devices such as charge-coupled device (CCD) image sensors and complementary metal-oxide-semiconductor (CMOS) image sensors are known. Various studies have been conducted on imaging devices.

For example, an imaging device having a configuration for realizing a wide dynamic range has been proposed. An imaging device in Japanese Patent No. 4018820 has a one-pixel two-cell structure. Specifically, in the imaging device in Japanese Patent No. 4018820, a photodiode with a large area is arranged in a high-sensitivity cell, and a photodiode with a small area is arranged in a low-sensitivity cell.

Additionally, for example, a multilayer imaging device with a photoelectric converter arranged above a semiconductor substrate has been proposed. In the multilayer imaging device, charge generated by photoelectric conversion is accumulated in a charge accumulator. An electric signal according to the amount of the charge accumulated in the charge accumulator is read out through a CCD circuit or a CMOS circuit provided on the semiconductor substrate. Japanese Patent No. 6213743 discloses such a multilayer imaging device.

### SUMMARY

One non-limiting and exemplary embodiment provides techniques suitable for realizing a high-quality imaging device.

In one general aspect, the techniques disclosed here feature an imaging device including: a semiconductor substrate; and a pixel including a first cell, a second cell that is less sensitive than the first cell, and an upper wiring layer located above the semiconductor substrate and including wires. The first cell includes: a first photoelectric converter that converts light into first signal charge; a first charge accumulator located within the semiconductor substrate, accumulating the first signal charge, and electrically connected to a first node; and a first wire located within the upper wiring layer and electrically connected to the first node. The second cell includes: a second photoelectric converter that converts light into second signal charge; a second charge accumulator located within the semiconductor substrate, accumulating the second signal charge, and electrically connected to a second node; and a second wire located within the upper wiring layer and electrically connected to the second node. Nodes to which the wires are respectively electrically connected are different from both the first node and the second node. In the upper wiring layer, a shortest distance between the first wire and the wires is greater than a shortest distance between the second wire and the wires.

Techniques according to the present disclosure are suitable for realizing a high-quality imaging device.

Additional benefits and advantages of the disclosed embodiments will become apparent from the specification and drawings. The benefits and/or advantages may be individually obtained by the various embodiments and features of the specification and drawings, which need not all be provided in order to obtain one or more of such benefits and/or advantages.

### BRIEF DESCRIPTION OF THE DRAWINGS

FIG. 1 is an exemplary configuration diagram of an imaging device according to an embodiment;

FIG. 2 is an exemplary circuit diagram of a pixel according to the embodiment;

FIG. 3 is a schematic configuration diagram of a pixel related to a cross-section parallel in a thickness direction of a semiconductor substrate;

FIG. 4 is a plan view illustrating a microlens group;

FIG. 5 is a plan view of a pixel electrode and the like;

FIG. 6 is a schematic partially enlarged view of a capacitor element having a trench structure;

FIG. 7 is a circuit diagram of a pixel according to another example of the embodiment;

FIG. 8A is a circuit diagram in which overflow transistors are applied to the circuit diagram of FIG. 2;

FIG. 8B is a circuit diagram in which overflow transistors are applied to the circuit diagram of FIG. 7;

FIG. 9 is a diagram of a circuit configuration using photodiodes;

FIG. 10A is a schematic configuration diagram of a gate wiring layer in plan view;

FIG. 10B is a schematic configuration diagram of a first wiring layer in plan view;

FIG. 10C is a schematic configuration diagram of a metal-insulator-metal (MIM) hierarchy in plan view;

FIG. 10D is a schematic configuration diagram of a second wiring layer in plan view;

FIG. 10E is a schematic configuration diagram of a third wiring layer in plan view;

FIG. 10F is a schematic configuration diagram of a fourth wiring layer in plan view;

FIG. 10G is a schematic configuration diagram of a fifth wiring layer in plan view;

FIG. 10H is a schematic configuration diagram of a sixth wiring layer in plan view;

FIG. 10I is a schematic configuration diagram of a pixel electrode hierarchy in plan view;

FIG. 11A is a schematic configuration diagram of the gate wiring layer in plan view, corresponding to the configuration illustrated in FIG. 8A;

FIG. 11B is a schematic configuration diagram of the first wiring layer in plan view, corresponding to the configuration illustrated in FIG. 8B;

FIG. 11C is a schematic configuration diagram of the second wiring layer in plan view, corresponding to the configuration illustrated in FIG. 8B; and

FIG. 12 is a schematic plan view for describing the relationship between area ratios.

### DETAILED DESCRIPTIONS

### Underlying Knowledge Forming Basis of the Present Disclosure

The inventors have studied an imaging device with a one-pixel two-cell structure. The imaging device according to this study has high-sensitivity cells and high-saturation cells. The high-sensitivity cells have higher sensitivity compared to the high-saturation cells. The high-saturation cells have a larger saturation charge amount compared to the high-sensitivity cells. The high-sensitivity cells and high-saturation cells each have a photoelectric converter that converts light into signal charge, and a charge accumulator that accumulates the signal charge. In each of the high-sensitivity cells and high-saturation cells, the charge accumulator is located within the semiconductor substrate.

In order to improve the image quality of the imaging device with a one-pixel two-cell structure as mentioned above, it is effective to reduce noise in the high-sensitivity cells. In order to reduce noise in the high-sensitivity cells, it is effective to increase the conversion gain of the high-sensitivity cells.

Here, the term “charge accumulation node” is used. The charge accumulation node is a node to which the charge accumulator is electrically connected. The charge accumulation node is also referred to as a floating diffusion node. Additionally, the term “the capacitance of the charge accumulation node” is used. The capacitance of the charge accumulation node is the whole capacitance electrically connected to the charge accumulation node. Furthermore, the term “the capacitance value of the charge accumulation node” is used. The capacitance value of the charge accumulation node is the capacitance value of the capacitance of the charge accumulation node. The capacitance of the charge accumulation node may include, along with the charge accumulator, the parasitic capacitance between the electrical path connecting the photoelectric converter and the charge accumulator and other structures. The capacitance value of the charge accumulation node may include, along with the capacitance value of the charge accumulator, the capacitance value of the above-mentioned parasitic capacitance.

In order to increase the conversion gain of the high-sensitivity cells, it is effective to reduce the capacitance value of the charge accumulation node of the high-sensitivity cells. In order to reduce the capacitance value of the charge accumulation node of the high-sensitivity cells, it is effective to reduce the capacitance value of the above-mentioned parasitic capacitance in the high-sensitivity cells. In view of the above, the present disclosure provides techniques suitable for realizing a high-quality imaging device.

### Outline of One Aspect of the Present Disclosure

An imaging device according to a first aspect of the present disclosure includes:
a semiconductor substrate; and
a pixel including a first cell, a second cell that is less sensitive than the first cell, and an upper wiring layer located above the semiconductor substrate and including wires,
the first cell including:
   a first photoelectric converter that converts light into first signal charge;
   a first charge accumulator located within the semiconductor substrate, accumulating the first signal charge, and electrically connected to a first node; and
   a first wire located within the upper wiring layer and electrically connected to the first node,
the second cell including
   a second photoelectric converter that converts light into second signal charge;
   a second charge accumulator located within the semiconductor substrate, accumulating the second signal charge, and electrically connected to a second node; and
   a second wire located within the upper wiring layer and electrically connected to the second node,
wherein nodes to which the wires are respectively electrically connected are different from both the first node and the second node, and
in the upper wiring layer,
   a shortest distance between the first wire and the wires is greater than a shortest distance between the second wire and the wires.

The first aspect is suitable for realizing a high-quality imaging device.

In a second aspect of the present disclosure, for example, in the imaging device according to the first aspect,
the pixel may include a first capacitance wiring layer located above the semiconductor substrate,
the first capacitance wiring layer may include:
   a first predetermined wire electrically connected to the first node; and
   a first specific wire electrically connected to a specific node different from the first node,
the first cell may include a specific capacitor element, and
the specific capacitor element may include the first predetermined wire and the first specific wire.

The second aspect is suitable for realizing a specific capacitor element with high accuracy and a micro-capacitance value.

In a third aspect of the present disclosure, for example, in the imaging device according to the second aspect,
the pixel may include a second capacitance wiring layer located above the semiconductor substrate and above or below the first capacitance wiring layer,
the second capacitance wiring layer may include:
   a second predetermined wire electrically connected to the first node; and
   a second specific wire electrically connected to the specific node, and
the specific capacitor element may include the second predetermined wire and the second specific wire.

According to the third aspect, it is easy to increase the ratio of the capacitance value of the specific capacitor element to the capacitance value of the specific node and to improve the accuracy of the capacitance value of the specific node.

In a fourth aspect of the present disclosure, for example, in the imaging device according to the second aspect or the third aspect,
in a cross-section that crosses the first capacitance wiring layer and that is perpendicular to a thickness direction of the semiconductor substrate, there may be a straight line that passes through a first portion of the first specific wire, a predetermined portion of the first predetermined wire, and a second portion of the first specific wire in this order.

According to the fourth aspect, it is easy to increase the ratio of the capacitance value of the specific capacitor element to the capacitance value of the specific node and to improve the accuracy of the capacitance value of the specific node.

In a fifth aspect of the present disclosure, for example, in the imaging device according to any one of the second to fourth aspects,
the first cell may include a first amplifier transistor that generates a first electric signal according to a potential of the first charge accumulator, and
the first electric signal may be negatively fed back to the first charge accumulator through the specific capacitor element.

According to the fifth aspect, the specific capacitor element can be used in negative feedback of the first electric signal.

In a sixth aspect of the present disclosure, for example, the imaging device according to any one of the second to fifth aspects may include:
a power supply wire electrically connected to a power supply node different from the first node, the second node, and the specific node,
wherein the first cell may include a first amplifier transistor that generates a first electric signal according to a potential of the first charge accumulator and that is supplied with a power supply potential through the power supply wire, and
in the first capacitance wiring layer, the first specific wire may be located between the power supply wire and the first predetermined wire.

According to the sixth aspect, the first specific wire may act as a shield for suppressing coupling between the power supply wire and the first predetermined wire.

In a seventh aspect of the present disclosure, for example, in the imaging device according to the sixth aspect,
the first electric signal may be negatively fed back to the first charge accumulator through the specific capacitor element, and
a potential of the first electric signal negatively fed back may be applied to the power supply wire.

According to the seventh aspect, even if a potential fluctuation occurs in the power supply wire due to negative feedback of the first electric signal, its impact on the capacitance of the first node can be suppressed by the shielding action mentioned above.

In an eighth aspect of the present disclosure, for example, in the imaging device according to any one of the second to seventh aspects,
the first cell may include a first capacitor element,
the first capacitor element may include a first electrode electrically connected to the specific node and a second electrode electrically isolated from the first electrode,
the first electrode may be located between the second electrode and the semiconductor substrate, and
a shortest distance between the first predetermined wire and the first specific wire in the first capacitance wiring layer may be less than a shortest distance between the first electrode and the semiconductor substrate.

According to the eighth aspect, it is easy to increase the ratio of the capacitance value of the specific capacitor element to the capacitance value of the specific node and to improve the accuracy of the capacitance value of the specific node.

In a ninth aspect of the present disclosure, for example, in the imaging device according to any one of the second to eighth aspects,
the first cell may include a MIM capacitor element or a MOS capacitor element electrically connected to the specific node.

The ninth aspect is suitable for increasing the capacitance value of the specific node.

In a tenth aspect of the present disclosure, for example, in the imaging device according to any one of the second to ninth aspects,
the wires may be all wires in the upper wiring layer excluding all wires electrically connected to the specific node.

The configuration of the tenth aspect is a configuration example of an imaging device.

In an eleventh aspect of the present disclosure, for example, in the imaging device according to any one of the first to ninth aspects,
the wires may be all wires in the upper wiring layer.

The configuration of the eleventh aspect is a configuration example of an imaging device.

An imaging device according to a twelfth aspect of the present disclosure includes:
a semiconductor substrate; and
a pixel including a first cell, a second cell that is less sensitive than the first cell, and an upper wiring layer located above the semiconductor substrate and including a first signal wire and a second signal wire,
the first cell including:
   a first photoelectric converter that converts light into first signal charge;
   a first charge accumulator located within the semiconductor substrate, accumulating the first signal charge, and electrically connected to a first node;
   a first wire located within the upper wiring layer and electrically connected to the first node; and
   a first transistor including a first source or a first drain that is the first charge accumulator and a first gate to which a first control signal is supplied through the first signal wire,
the second cell including:
   a second photoelectric converter that converts light into second signal charge;
   a second charge accumulator located within the semiconductor substrate, accumulating the second signal charge, and electrically connected to a second node;
   a second wire located within the upper wiring layer and electrically connected to the second node; and
   a second transistor including a second source or a second drain that is the second charge accumulator and a second gate to which a second control signal is supplied through the second signal wire,
wherein, in the upper wiring layer,
   a shortest distance between the first wire and the first signal wire is greater than a shortest distance between the second wire and the second signal wire.

The twelfth aspect is suitable for realizing a high-quality imaging device.

An imaging device according to a thirteenth aspect of the present disclosure includes:
a semiconductor substrate; and
a pixel including a first cell, a second cell that is less sensitive than the first cell, and an upper wiring layer located above the semiconductor substrate and including wires,
the first cell including:
   a first photoelectric converter that converts light into first signal charge;
   a first charge accumulator located within the semiconductor substrate, accumulating the first signal charge, and electrically connected to a first node; and
   a first wire located within the upper wiring layer and electrically connected to the first node,
the second cell including:
   a second photoelectric converter that converts light into second signal charge;
   a second charge accumulator located within the semiconductor substrate, accumulating the second signal charge, and electrically connected to a second node; and
   a second wire located within the upper wiring layer and electrically connected to the second node,
wherein nodes to which the wires are respectively electrically connected are different from both the first node and the second node, and
in a cross-section that crosses the upper wiring layer and that is perpendicular to a thickness direction of the semiconductor substrate, an area of the first wire is less than an area of the second wire.

The thirteenth aspect is suitable for realizing a high-quality imaging device.

An imaging device according to a fourteenth aspect of the present disclosure includes:
a semiconductor substrate; and
pixels arranged at a predetermined pitch,
the pixels including at least one pixel,
the at least one pixel including a first cell, a second cell that is less sensitive than the first cell, and an upper wiring layer located above the semiconductor substrate and including wires,
the first cell including:
   a first photoelectric converter that converts light into first signal charge;
   a first charge accumulator located within the semiconductor substrate, accumulating the first signal charge, and electrically connected to a first node; and
   a first wire located within the upper wiring layer and electrically connected to the first node,
the second cell including:
   a second photoelectric converter that converts light into second signal charge;
   a second charge accumulator located within the semiconductor substrate, accumulating the second signal charge, and electrically connected to a second node; and
   a second wire located within the upper wiring layer and electrically connected to the second node,
wherein nodes to which the wires are respectively electrically connected are different from both the first node and the second node, and
in a cross-section that crosses the upper wiring layer and that is perpendicular to a thickness direction of the semiconductor substrate,
   if a geometric center of the first wire is defined as a first central point,
   a geometric center of the second wire is defined as a second central point,
   a region surrounded by a circle centered on the first central point and having a radius of ⅛ of the pitch is defined as a first encircling region,
   a region surrounded by a circle centered on the second central point and having a radius of ⅛ of the pitch is defined as a second encircling region,
   a ratio of an area occupied by the wires in the first encircling region is defined as a first area ratio, and
   a ratio of an area occupied by the wires in the second encircling region is defined as a second area ratio,
then, the first area ratio is less than the second area ratio.

The fourteenth aspect is suitable for realizing a high-quality imaging device.

An imaging device according to a fifteenth aspect of the present disclosure includes:
a semiconductor substrate; and
a pixel including a first cell and a second cell that is less sensitive than the first cell,
the first cell including:
   a first photoelectric converter that converts light into first signal charge;
   a first charge accumulator located within the semiconductor substrate, accumulating the first signal charge, and electrically connected to a first node;
   a first plug electrically connected to the first node; and
   a first capacitor element having a first electrode and a second electrode,
the second cell including:
   a second photoelectric converter that converts light into second signal charge;
   a second charge accumulator located within the semiconductor substrate, accumulating the second signal charge, and electrically connected to a second node;
   a second plug electrically connected to the second node; and
   a second capacitor element having a third electrode and a fourth electrode,
wherein, in a cross-section that crosses the first capacitor element and that is perpendicular to a thickness direction of the semiconductor substrate,
   a shortest distance between the first plug and the second electrode is greater than a shortest distance between the second plug and the fourth electrode.

The fifteenth aspect is suitable for realizing a high-quality imaging device.

In a sixteenth aspect of the present disclosure, for example, in the imaging device according to the fifteenth aspect,
the first cell may include a first transistor,
the second cell may include a second transistor,
one of a source and a drain of the first transistor may be the first charge accumulator,
one of a source and a drain of the second transistor may be the second charge accumulator,
the first transistor and the first electrode may be electrically connected, and
the second transistor and the third electrode may be electrically connected.

The configuration of the sixteenth aspect is a configuration example of an imaging device.

An imaging device according to a seventeenth aspect of the present disclosure is
an imaging device including a semiconductor substrate and a pixel,
the pixel including:
   an upper wiring layer located above the semiconductor substrate and including a first signal wire;
   a first photoelectric converter that converts light into first signal charge;
   a first charge accumulator located within the semiconductor substrate, accumulating the first signal charge, and electrically connected to a first node;
   a first wire located within the upper wiring layer and electrically connected to the first node;
   a first plug electrically connected to the first node;
   a first capacitor element having a first electrode and a second electrode; and
   a first transistor including a first source or a first drain that is the first charge accumulator and a first gate to which a first control signal is supplied through the first signal wire,
wherein, in a cross-section that crosses the first capacitor element and that is perpendicular to a thickness direction of the semiconductor substrate, the first plug is located within a recess that is provided in the first capacitor element and that opens toward a predetermined direction, and
in the upper wiring layer, the first signal wire is located on the predetermined direction side relative to the first wire.

The seventeenth aspect is suitable for realizing a high-quality imaging device.

In an eighteenth aspect of the present disclosure, for example, the imaging device according to the seventeenth aspect may include
an intermediate wire that electrically connects the first plug and the first wire,
wherein, in a plan view, the intermediate wire may extend from a position within the recess to a position on the predetermined direction side relative to the recess.

According to the intermediate wire of the eighteenth aspect, it is easy to realize a positional relationship among the recess, the first plug, the first wire, and the first signal wire of the seventeenth aspect.

In a nineteenth aspect of the present disclosure, for example, in the imaging device according to the seventeenth aspect of the eighteenth aspect,
a ratio of a shortest distance between the first plug and the second electrode in the cross-section crossing the first capacitor element and perpendicular to the thickness direction of the semiconductor substrate to a shortest distance between the first wire and the first signal wire in the upper wiring layer may be greater than or equal to 0.5 and less than or equal to 2.

The nineteenth aspect is suitable for realizing a high-quality imaging device.

In a twentieth aspect of the present disclosure, for example, in the imaging device according to any one of the seventeenth to nineteenth aspects,
the pixel may include a first cell and a second cell that is less sensitive than the first cell, and
the first cell may include:
   the first photoelectric converter;
   the first charge accumulator;
   the first wire;
   the first plug;
   the first capacitor element; and
   the first transistor.

The twentieth aspect is suitable for realizing a high-quality imaging device.

Unless otherwise contradicted, the techniques of the first aspect to the twentieth aspect can be combined arbitrarily. For example, unless otherwise contradicted, some or all of at least one of the second to eleventh aspects can be combined with each of the twelfth aspect to the twentieth aspect. Additionally, unless otherwise contradicted, the first aspect, the twelfth aspect to the fifteenth aspect, and the seventeenth aspect can be combined.

Hereinafter, an embodiment of the present disclosure will be described in detail with reference to the drawings. The embodiment described below is all illustrative of comprehensive or specific examples. The numerical values, shapes, materials, components, component arrangement and connection forms, steps, and step sequences discussed in the following embodiment are merely examples and are not intended to limit the present disclosure. Various aspects described herein can be combined, unless otherwise contradicted. In the drawings, components having substantially the same functionality are assigned a common reference numeral to omit or simplify duplicate descriptions.

Various elements illustrated in the drawings are merely illustrated schematically for the understanding of the present disclosure, and dimensional ratios and appearances may differ from the actual objects.

In the embodiment, the terms such as “above”, “below”, “side”, etc. are used solely to specify the relative arrangement between members and are not intended to limit the orientation of an imaging device during use or the orientation of members of an imaging device being manufactured and a manufacturing device.

Ordinal words such as first, second, third, . . . may be used herein. In the case where a certain element is assigned an ordinal number, it is not essential that there exists an element of the same type with a lower number. Ordinal numbers can be changed, as necessary. Ordinal numbers are not intended to be interpreted as limiting the elements to which they are assigned. The same applies to the terms “specific” and “predetermined”.

In the embodiment, “plan view” refers to the view when looking from the thickness direction of a semiconductor substrate.

In the embodiment, the polarity of transistors and the conductivity type of impurity regions are examples. Unless otherwise contradicted, the polarity of transistors and the conductivity type of impurity regions may be inverted.

In the embodiment, the expression “element A is connected to element B” may be used. This expression encompasses cases where part or all of element A is contained within part or all of element B. Additionally, this expression encompasses not only cases where element A and element B are directly connected but also cases where element A and element B are indirectly connected through another element.

In the embodiment, the expression “element A is electrically connected to element B” may be used. This expression means that element A is connected to element B at the same potential. Note that, in the embodiment, unless otherwise contradicted, “connected” and “electrically connected” can be used interchangeably.

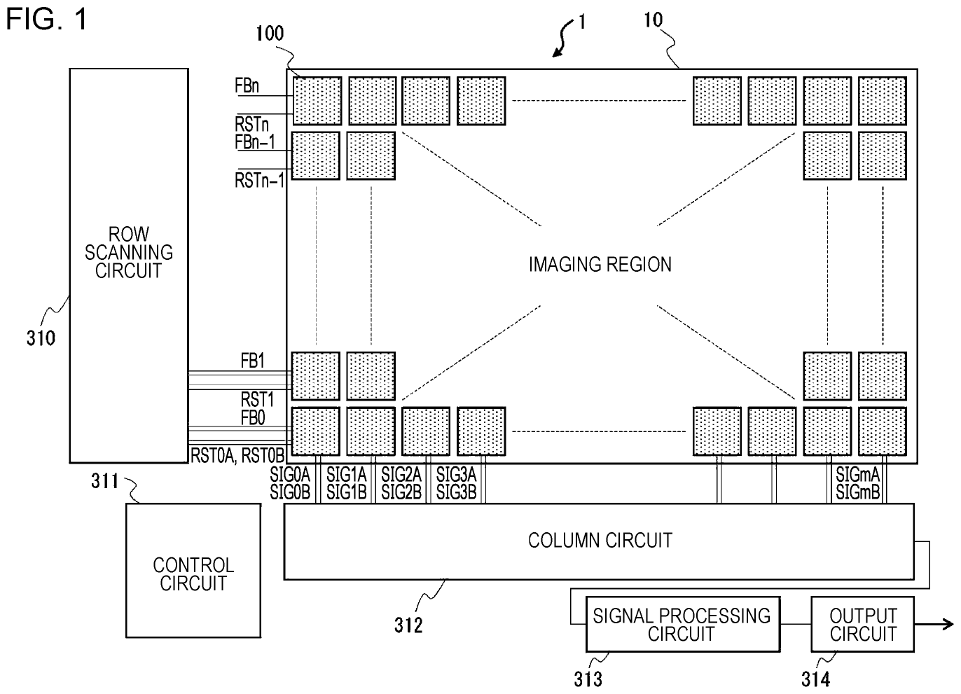

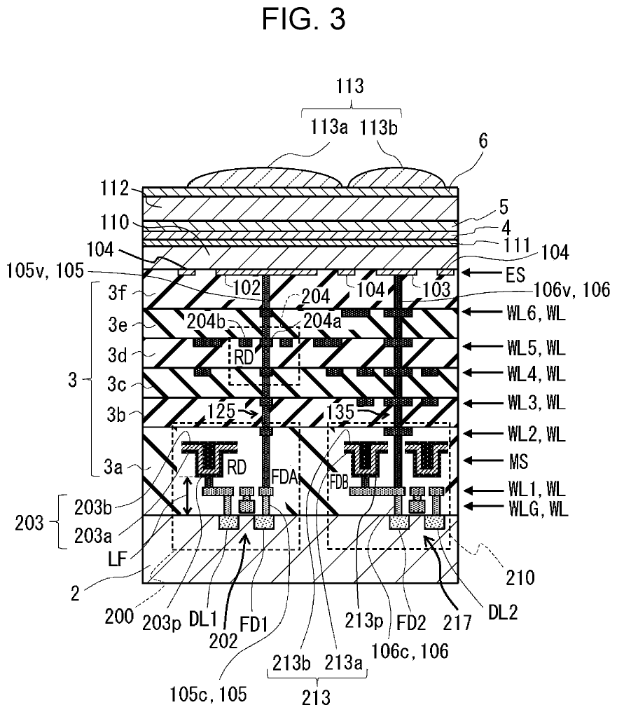

FIG. 1 is an exemplary configuration diagram of an imaging device 1 according to the embodiment. The imaging device 1 has a pixel array 10 and peripheral circuits. The pixel array 10 includes pixels 100, which form an imaging region. In this example, the pixels 100 are arranged in two dimensions on a semiconductor substrate 2 (see FIG. 3). Specifically, the pixels 100 are arranged in a matrix of m rows by n columns. More specifically, the center of each pixel 100 is located on a lattice point of a square lattice.

The arrangement of the pixels 100 is not limited to the illustrated example. For example, the center of each pixel 100 may be located on a lattice point of a triangular lattice, a hexagonal lattice, or the like. The pixels 100 may be arrayed in one dimension. That is, the arrangement of the pixels 100 may be m rows by one column or one row by n columns. In this case, the imaging device 1 can be used as a line sensor. The number of the pixels 100 in the imaging device 1 may be one.

In the configuration illustrated in FIG. 1, the peripheral circuits include a row scanning circuit 310, a column circuit 312, a signal processing circuit 313, an output circuit 314, and a control circuit 311. The pixel array 10 and the peripheral circuits may be arranged on the same semiconductor substrate 2. The pixel array 10 may be arranged on the semiconductor substrate 2, and the peripheral circuits may be arranged on another semiconductor substrate. The pixel array 10 may be arranged on the semiconductor substrate 2, some portions of the peripheral circuits may be arranged on the semiconductor substrate 2, and other portions of the peripheral circuits may be arranged on another semiconductor substrate.

The row scanning circuit 310 is connected to a first reset control line RSTiA, a second reset control line RSTiB, and a feedback control line FBi. The first reset control line RSTiA, the second reset control line RSTiB, and the feedback control line FBi are provided corresponding to each row of the pixel array 10. That is, among the pixels 100, one or more pixels 100 that belong to an i-th row are connected to the first reset control line RSTiA, the second reset control line RSTiB, and the feedback control line FBi. Here, i ranges from 0 to n−1, and n is an integer greater than or equal to 1.

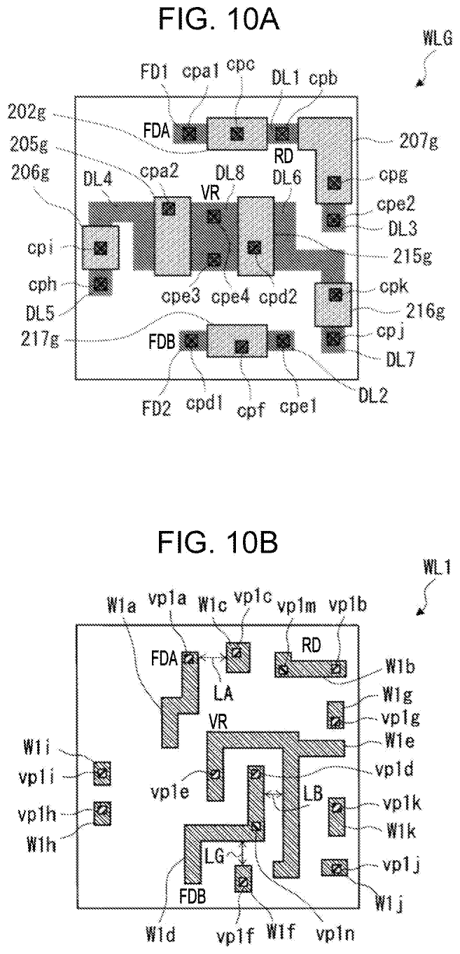

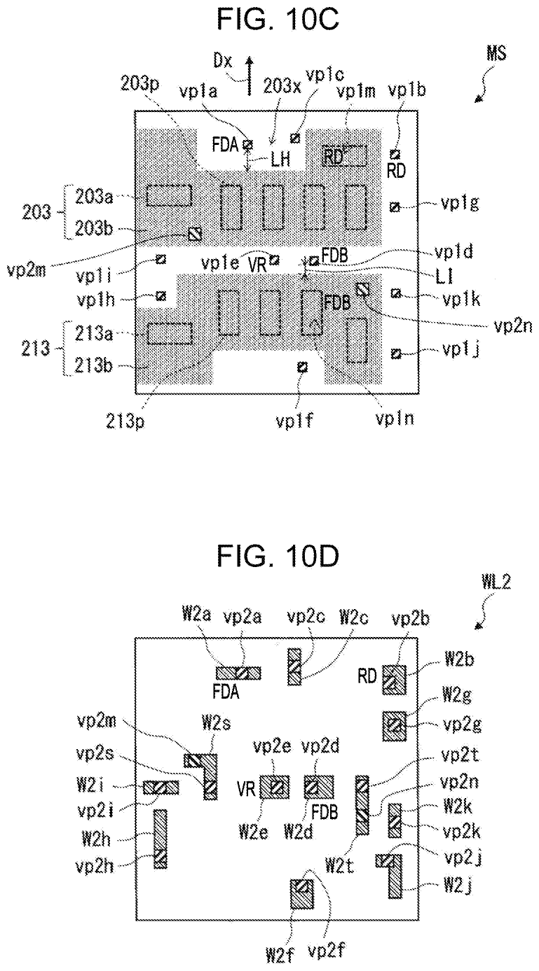

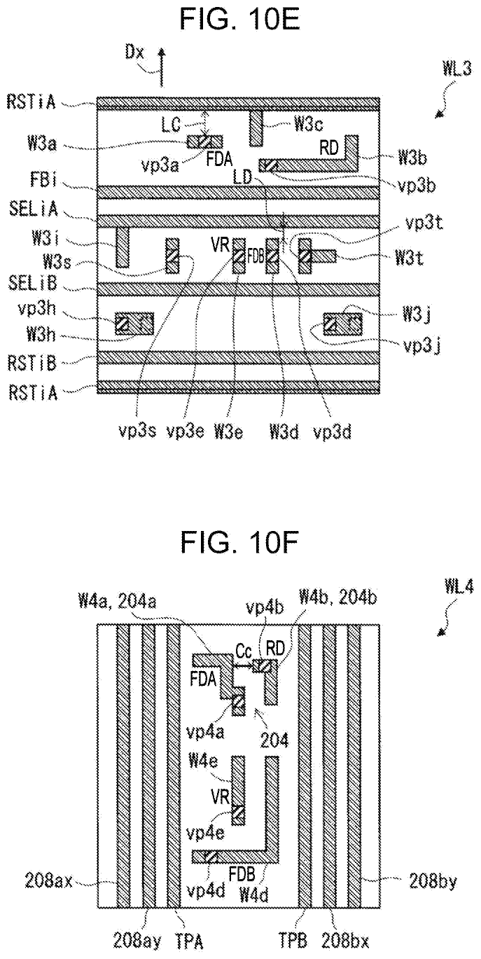

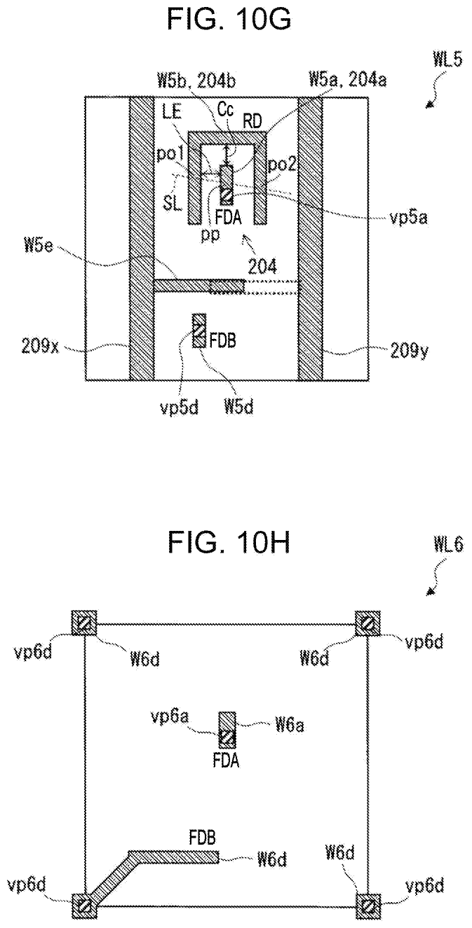

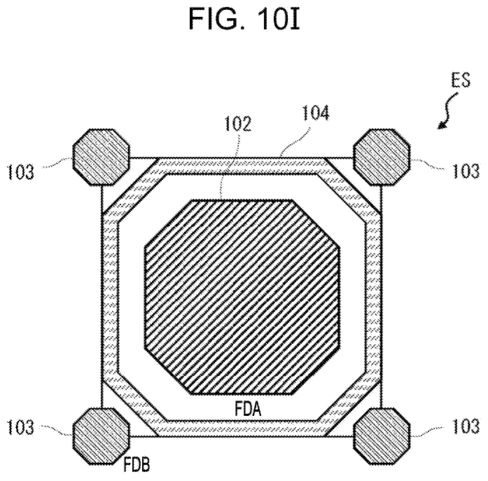

The row scanning circuit 310 is connected to a first address control line SELiA and a second address control line SELiB, which are not illustrated in FIG. 1 (see FIG. 10E). The first address control line SELiA and the second address control line SELiB are also provided corresponding to each row of the pixel array 10, and are connected to one or more pixels 100 belonging to the i-th row, like the first reset control line RSTIA, the second reset control line RSTiB, and the feedback control line FBi. The row scanning circuit 310 selects the pixels 100 in units of rows by applying a predetermined potential to the first address control line SELiA and the second address control line SELiB, reading out electric signals and performing a later-described reset operation. The row scanning circuit 310 is also referred to as a vertical scanning circuit.

The column circuit 312 is connected to a first vertical signal line SIGjA and a second vertical signal line SIGjB provided corresponding to each column of the pixel array 10. Here, j ranges from 0 to m−1, and m is an integer greater than or equal to 1. Among the pixels 100, one or more pixels 100 that belong to a j-th column are connected to the first vertical signal line SIGjA and the second vertical signal line SIGjB, and electric signals output from the pixels 100 selected in units of rows by the row scanning circuit 310 are read out to the column circuit 312 through the first vertical signal line SIGjA and the second vertical signal line SIGjB. The column circuit 312 performs noise suppression signal processing, analog-to-digital conversion (AD conversion), and the like on the electric signals read out from the pixels 100. Noise suppression signal processing is, for example, correlated double sampling.

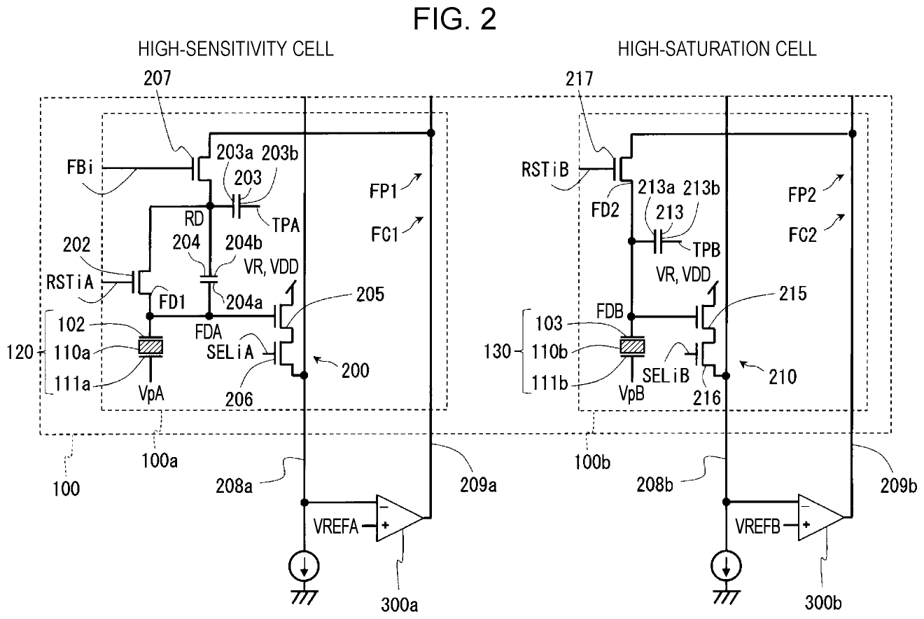

The signal processing circuit 313 applies various processes on image signals obtained from the pixels 100. As used herein, “image signals” refer to, among electric signals read out through the first vertical signal line SIGjA and the second vertical signal line SIGjB, those used to form an image. Each pixel 100 includes a high-sensitivity first cell 100a and a low-sensitivity and high-saturation second cell 100b (see FIG. 2). A high-sensitivity image signal is read out from the first cell 100a, and a low-sensitivity image signal is read out from the second cell 100b. Based on the high-sensitivity image signal and the low-sensitivity image signal, the signal processing circuit 313 forms a wide-dynamic-range image. The output of the signal processing circuit 313 is read out to the outside of the imaging device 1 through the output circuit 314.

The control circuit 311 receives command data, clocks, etc. The command data, clocks, etc. are provided from, for example, the outside of the imaging device 1. Based on the received command data, clocks, etc., the control circuit 311 controls the entire imaging device 1. The control circuit 311 typically has a timing generator, which supplies drive signals to the row scanning circuit 310, the column circuit 312, etc.

FIG. 2 is an exemplary circuit diagram of a pixel 100 according to the embodiment. One pixel 100 has the first cell 100a and the second cell 100b. The first cell 100a has higher sensitivity compared to the second cell 100b. The second cell 100b has a higher saturation level compared to the first cell 100a. That is, the saturation charge amount of the second cell 100b is greater than the saturation charge amount of the first cell 100a. The first cell 100a may also be referred to as a high-sensitivity cell or a first imaging cell. The second cell 100b may also be referred to as a high-saturation cell or a second imaging cell.

The first cell 100a is responsible for imaging regions of relatively low illuminance. The first cell 100a functions as a low-noise cell. In contrast, the second cell 100b is responsible for imaging regions of relatively high illuminance. The second cell 100b functions as a dynamic range expansion cell that expands the dynamic range on the high illuminance side. The use of the first cell 100a and the second cell 100b facilitates imaging of scenes over a wide dynamic range.

The first cell 100a has a first microlens 113a (see FIG. 3), a first photoelectric converter 120, and a first signal detection circuit 200. Light is incident on the first photoelectric converter 120 through the first microlens 113a. The first photoelectric converter 120 converts this light into first signal charge. The first signal detection circuit 200 is electrically connected to the first photoelectric converter 120. The first signal detection circuit 200 reads out a first electric signal based on the first signal charge generated by the first photoelectric converter 120. In the present embodiment, the first signal detection circuit 200 is a metal-oxide-semiconductor (MOS) circuit. The first signal detection circuit 200 may be a thin-film transistor (TFT) circuit.

In the present embodiment, the imaging device 1 is of a multilayer type. The first cell 100a is of a multilayer type. The first photoelectric converter 120 is provided on the semiconductor substrate 2. The first photoelectric converter 120 has a first pixel electrode 102, a first opposing electrode 111a, and a first photoelectric conversion film 110a. The first photoelectric conversion film 110a is arranged between the first pixel electrode 102 and the first opposing electrode 111a.

Typically, the first pixel electrode 102 is provided for each pixel 100. The first pixel electrode 102 and the first pixel electrode 102 that are adjacent to each other are electrically isolated. The first pixel electrode 102 is electrically connected to a first node FDA. The first node FDA may be referred to as a first charge accumulation node, a first floating diffusion node, or the like. Hereinafter, the whole capacitance of a capacitor electrically connected to the first node FDA may be referred to as the capacitance of the first node FDA. The capacitance value of the capacitance of the first node FDA may be referred to as the capacitance value of the first node FDA.

The first opposing electrode 111a is arranged on the light-receiving side of the first photoelectric conversion film 110a. The first opposing electrode 111a is transparent and conductive. During the operation of the imaging device 1, a predetermined potential VpA is applied to the first opposing electrode 111a.

By applying the potential VpA to the first opposing electrode 111a, among hole-electron pairs generated by photoelectric conversion at the first opposing electrode 111a, either holes or electrons can be collected by the first pixel electrode 102. In the case of using holes as the first signal charge, as the potential VpA, a potential of about 10 V, for example, is applied to the first opposing electrode 111a. By setting the potential of the first opposing electrode 111a higher than that of the first pixel electrode 102, holes can be accumulated in the capacitance of the first node FDA. Hereinafter, an example of using holes as the first signal charge will be described. Needless to say, electrons may be used as the first signal charge.

The first signal detection circuit 200 has a first amplifier transistor 205, a first selection transistor 206, a first reset transistor 202, and a first feedback circuit FC1.

In the present embodiment, transistors are metal-oxide-semiconductor field-effect transistors (MOSFETs), and specifically N-channel MOSFETs. The transistors are provided on the semiconductor substrate 2. The semiconductor substrate 2 is not limited to a substrate that is entirely composed of a semiconductor material. The semiconductor substrate 2 may have an insulating layer and a semiconductor layer. The transistors may be provided on the semiconductor layer. A photosensitive region may be provided on the side of the semiconductor layer. The transistors may be thin-film transistors (TFTs). These points apply not only to the first cell 100a but also to the second cell 100b.

A control terminal of the first amplifier transistor 205 is electrically connected to the first node FDA. In the present embodiment, the control terminal of the first amplifier transistor 205 is the gate.

The gate of the first amplifier transistor 205 is electrically connected to the first photoelectric converter 120, specifically to the first pixel electrode 102. A potential according to the amount of the first signal charge generated by the first photoelectric converter 120 is applied to the gate. The first amplifier transistor 205 generates a first electric signal according to the applied potential.

One of the source and drain of the first amplifier transistor 205 is electrically connected to one of the source and drain of the first selection transistor 206. The other of the source and drain of the first amplifier transistor 205 is electrically connected to a power supply node VR to which a power supply potential VDD is applied. The other of the source and drain of the first selection transistor 206 is electrically connected to a first vertical signal line 208a. The first selection transistor 206 selectively outputs the first electric signal generated by the first amplifier transistor 205 to the first vertical signal line 208a. The first vertical signal line 208a corresponds to the first vertical signal line SIGjA illustrated in FIG. 1.

One of the source and drain of the first reset transistor 202 is electrically connected to the first node FDA. The first reset transistor 202 resets (initializes) the potential of the capacitance of the first node FDA. In the present embodiment, one of the source and drain of the first reset transistor 202 is a first charge accumulator FD1.

The first feedback circuit FC1 includes a band control transistor 207, a first inverting amplifier 300a, a first capacitor element 203, and a specific capacitor element 204.

A first reference potential VREFA is applied to a first input terminal of the first inverting amplifier 300a. The first vertical signal line 208a is electrically connected to a second input terminal of the first inverting amplifier 300a. One of the source and drain of the band control transistor 207 is electrically connected to an output terminal of the first inverting amplifier 300a through a first feedback line 209a provided corresponding to each column. The other of the source and drain of the band control transistor 207 is electrically connected to a specific node RD. The other of the source and drain of the first reset transistor 202, the first capacitor element 203, and the specific capacitor element 204 are electrically connected to the specific node RD.

The first capacitor element 203 has an electrode 203a and an electrode 203b. The electrode 203a is electrically connected to the specific node RD. A potential is applied to the electrode 203b through a first capacitance control line TPA. The capacitance value of the first capacitor element 203 is greater than the capacitance value of the specific capacitor element 204.

The specific capacitor element 204 has a predetermined electrode 204a and a specific electrode 204b. The predetermined electrode 204a is electrically connected to the first node FDA. The specific electrode 204b is electrically connected to the first specific node RD.

The band control transistor 207 performs band control of the first feedback circuit FC1. The first feedback circuit FC1 includes a first feedback path FP1. The first feedback path FP1 includes the first inverting amplifier 300a, the band control transistor 207, and the specific capacitor element 204 in this order. The first feedback path FP1 negatively feeds back kTC noise, generated when turning off the first reset transistor 202, to the capacitance of the first node FDA. The first inverting amplifier 300a can increase the gain of the first feedback path FP1 and improve the noise suppression effect.

The first feedback line 209a is provided corresponding to each column. The first feedback line 209a connects the first cells 100a belonging to that column. This realizes column feedback for the first cells 100a belonging to that column.

The second cell 100b has a second microlens 113b (see FIG. 3), a second photoelectric converter 130, and a second signal detection circuit 210. Light is incident on the second photoelectric converter 130 through the second microlens 113b. The second photoelectric converter 130 converts this light into second signal charge. The second signal detection circuit 210 is electrically connected to the second photoelectric converter 130. The second signal detection circuit 210 reads out a second electric signal based on the second signal charge generated by the second photoelectric converter 130. In the present embodiment, the second signal detection circuit 210 is a MOS circuit. The second signal detection circuit 210 may be a TFT circuit.

In the present embodiment, the second cell 100b is of a multilayer type. The second photoelectric converter 130 is provided on the semiconductor substrate 2. The second photoelectric converter 130 has a second pixel electrode 103, a second opposing electrode 111b, and a second photoelectric conversion film 110b. The second photoelectric conversion film 110b is arranged between the second pixel electrode 103 and the second opposing electrode 111b.

Typically, the second pixel electrode 103 is provided for each pixel 100. The second pixel electrode 103 and the second pixel electrode 103 that are adjacent to each other are electrically isolated. The second pixel electrode 103 is electrically connected to a second node FDB. The second node FDB may be referred to as a second charge accumulation node, a second floating diffusion node, or the like. Hereinafter, the whole capacitance electrically connected to the second node FDB may be referred to as the capacitance of the second node FDB. The capacitance value of the capacitance of the second node FDB may be referred to as the capacitance value of the second node FDB. The capacitance value of the second node FDB is greater compared to the capacitance value of the first node FDA.

The second opposing electrode 111b is arranged on the light-receiving side of the second photoelectric conversion film 110b. The second opposing electrode 111b is transparent and conductive. During the operation of the imaging device 1, a predetermined potential VpB is applied to the second opposing electrode 111b.

By applying the potential VpB to the second opposing electrode 111b, among hole-electron pairs generated by photoelectric conversion at the second opposing electrode 111b, either holes or electrons can be collected by the second pixel electrode 103. In the case of using holes as the second signal charge, as the potential VpB, a potential of about 10 V, for example, is applied to the second opposing electrode 111b. By making the potential of the second opposing electrode 111b higher than the potential of the second pixel electrode 103, holes can be accumulated in the capacitance of the second node FDB. Hereinafter, an example of using holes as the second signal charge will be described. Needless to say, electrons may be used as the second signal charge.

The second signal detection circuit 210 has a second amplifier transistor 215, a second selection transistor 216, a second capacitor element 213, and a second feedback circuit FC2.

A control terminal of the second amplifier transistor 215 is electrically connected to the second node FDB. In the present embodiment, the control terminal of the second amplifier transistor 215 is the gate.

The gate of the second amplifier transistor 215 is electrically connected to the second photoelectric converter 130, specifically to the second pixel electrode 103. A potential according to the amount of the second signal charge generated by the second photoelectric converter 130 is applied to the gate. The second amplifier transistor 215 generates a second electric signal according to the applied potential.

One of the source and drain of the second amplifier transistor 215 is electrically connected to one of the source and drain of the second selection transistor 216. The other of the source and drain of the second amplifier transistor 215 is electrically connected to the power supply node VR to which the power supply potential VDD is applied. The other of the source and drain of the second selection transistor 216 is electrically connected to a second vertical signal line 208b. The second selection transistor 216 selectively outputs the second electric signal generated by the second amplifier transistor 215 to the second vertical signal line 208b. The second vertical signal line 208b corresponds to the second vertical signal line SIGjB illustrated in FIG. 1.

One of the source and drain of a second reset transistor 217 is electrically connected to the second node FDB. The second reset transistor 217 resets (initializes) the potential of the capacitance of the second node FDB. In the present embodiment, one of the source and drain of the second reset transistor 217 is a second charge accumulator FD2.

The second capacitor element 213 is electrically connected to the second node FDB. The second capacitor element 213 improves the high saturation characteristics of the second cell 100b and expands the dynamic range of the imaging device 1.

The second feedback circuit FC2 includes the second reset transistor 217 and a second inverting amplifier 300b.

A second reference potential VREFB is applied to a first input terminal of the second inverting amplifier 300b. The second vertical signal line 208b is electrically connected to a second input terminal of the second inverting amplifier 300b. The other of the source and drain of the second reset transistor 217 is electrically connected to an output terminal of the second inverting amplifier 300b through a second feedback line 209b provided corresponding to each column.

The second capacitor element 213 has an electrode 213a and an electrode 213b. The electrode 213a is electrically connected to the second node FDB. A potential is applied to the electrode 213b through a second capacitance control line TPB.

The second feedback circuit FC2 includes a second feedback path FP2. The second feedback path FP2 includes the second inverting amplifier 300b and the second reset transistor 217. The second feedback path FP2 negatively feeds back kTC noise, generated when turning off the second reset transistor 217, to the capacitance of the second node FDB. The second inverting amplifier 300b can increase the gain of the second feedback path FP2 and improve the noise suppression effect.

The second feedback line 209b is provided corresponding to each column. The second feedback line 209b connects second cells 100b belonging to that column. This realizes column feedback for the second cells 100b belonging to that column.

The first cell 100a and the second cell 100b may have at least one configuration selected from the configurations listed below. These configurations may contribute to making the sensitivity of the first cell 100a higher than the sensitivity of the second cell 100b:
in a plan view, the light collection area of the first microlens 113a is greater than the light collection area of the second microlens 113b; and
in a plan view, the area of the first pixel electrode 102 is greater than the area in plan view of the second pixel electrode 103.

As mentioned earlier, the first cell 100a and the second cell 100b have characteristics listed below:
the first cell 100a has higher sensitivity compared to the second cell 100b;
the first cell 100a has lower noise compared to the second cell 100b;
the second cell 100b has a higher saturation level compared to the first cell 100a; and
the capacitance value of the second node FDB is greater compared to the capacitance value of the first node FDA.

The expression “the first cell 100a has higher sensitivity compared to the second cell 100b” will be described. In the present embodiment, this expression means that, while white light of a certain amount of light is incident on the imaging device 1, the amount of the first signal charge generated is greater than the amount of the second signal charge generated. The sensitivity depends on the area of the microlenses and the pixel electrodes.

The expression “the first cell 100a has lower noise compared to the second cell 100b” will be described. In the present embodiment, this expression means that, while white light of a certain amount of light is incident on the imaging device 1, the absolute value of noise of the first electric signal derived from the incident light on the first cell 100a is greater than the absolute value of noise of the second electric signal derived from the incident light on the second cell 100b.

The expression “the second cell 100b has a higher saturation level compared to the first cell 100a” will be described. In the present embodiment, this expression means that, while the amount of white light incident on the imaging device 1 gradually increases, a second timing appears subsequent to a first timing. The second timing is the moment when the rise in the level of the second electric signal, which is derived from the incident light on the second cell 100b, reaches a plateau. The first timing is the moment when the rise in the level of the first electric signal, which is derived from the incident light on the first cell 100a, reaches a plateau.

The first cells 100a are responsible for imaging dark scenes. Therefore, the need for the first cells 100a to have high saturation characteristics is relatively low. In the meantime, the need for the first cells 100a to have low noise characteristics is relatively high.

In contrast, the second cells 100b are responsible for imaging bright scenes. Therefore, the need for the second cells 100b to have high saturation characteristics is relatively high. In the meantime, the need for the second cells 100b to have low noise characteristics is relatively low. This is because the amount of light is large in imaging bright scenes, and the effect of dark current shot noise on image quality is reduced.

Each first cell 100a has the first feedback circuit FC1. Therefore, noise generated when turning off the first reset transistor 202 can be suppressed. Each second cell 100b has the second feedback circuit FC2. Therefore, noise generated when turning off the second reset transistor 217 can be suppressed.

FIG. 3 is a schematic configuration diagram of the pixel 100 related to a cross-section parallel in the thickness direction of the semiconductor substrate 2. Insulating layers 3 are provided above the semiconductor substrate 2. The pixel 100 is configured using the semiconductor substrate 2 and the insulating layers 3.

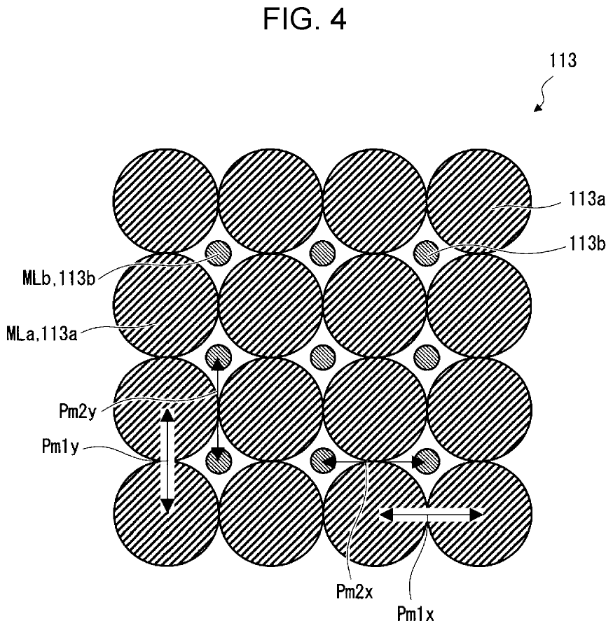

The pixel 100 has a continuous microlens group 113. In the example illustrated in FIG. 3, in one pixel 100, the microlens group 113 includes a first microlens 113a and a second microlens 113b. FIG. 4 is a plan view illustrating the microlens group 113. In FIG. 4, symbols MLa and MLb respectively denote the first microlens 113a and the second microlens 113b belonging to the same pixel 100. Note that each microlens group refers to two or more microlenses.

The microlens group 113 may be provided across all pixels 100. There may be pixel blocks, each having the microlens group 113 arranged across pixels 100. The microlens group 113 may be independently provided for each pixel 100. Additionally, in one pixel 100, the first microlens 113a and the second microlens 113b may be isolated from each other.

The pixel 100 has a continuous photoelectric conversion film 110. In the example illustrated in FIG. 3, in one pixel 100, the photoelectric conversion film 110 includes the first photoelectric conversion film 110a and the second photoelectric conversion film 110b. The photoelectric conversion film 110 may have a uniform film thickness in the pixel array 10.

The photoelectric conversion film 110 may be provided across all pixels 100. There may be pixel blocks, each having the photoelectric conversion film 110 arranged across pixels 100. The photoelectric conversion film 110 may be independently provided for each pixel 100. Additionally, in one pixel 100, the first photoelectric conversion film 110a and the second photoelectric conversion film 110b may be isolated from each other.

The pixel 100 has a continuous opposing electrode 111. In the example illustrated in FIG. 3, in one pixel 100, the opposing electrode 111 includes the first opposing electrode 111a and the second opposing electrode 111b. During the operation of the imaging device 1, a predetermined potential Vp is applied to the opposing electrode 111. Therefore, both the potential VpA applied to the first opposing electrode 111a and the potential VpB applied to the second opposing electrode 111b are the potential Vp and are the same.

The opposing electrode 111 may be provided across all pixels 100. In this case, a common potential can be supplied to the opposing electrode 111 of all the pixels 100. There may be pixel blocks, each having the opposing electrode 111 arranged across pixels 100. It is acceptable to supply different potentials to the opposing electrodes 111 in units of pixel blocks. In this case, the sensitivity of the pixels 100 can be varied in units of pixel blocks. The opposing electrode 111 may be independently provided for each pixel 100. It is acceptable to supply different potentials to the opposing electrodes 111 in units of pixels 100. In this case, the sensitivity can be varied in units of pixels 100. Additionally, in one pixel 100, the first opposing electrode 111a and the second opposing electrode 111b may be isolated from each other.

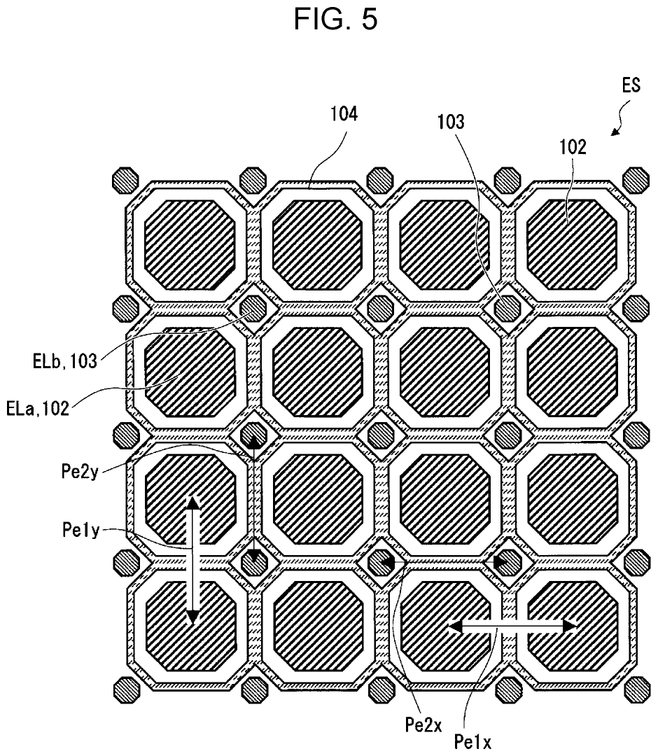

The pixel 100 has an auxiliary electrode 104. FIG. 5 is a plan view of the first pixel electrode 102, the second pixel electrode 103, and the auxiliary electrode 104. In FIG. 5, symbols ELa and ELb respectively denote the first pixel electrode 102 and the second pixel electrode 103 belonging to the same pixel 100. Hereinafter, the term “pixel electrode hierarchy ES” is used. The pixel electrode hierarchy ES of the present embodiment includes the first pixel electrode 102, the second pixel electrode 103, and the auxiliary electrode 104. The pixel electrode hierarchy ES is illustrated in FIG. 3.

As illustrated in FIG. 5, in a plan view, the auxiliary electrode 104 is arranged between the first pixel electrode 102 and the second pixel electrode 103. In a plan view, the auxiliary electrode 104 is arranged between the first pixel electrode 102 and the first pixel electrode 102 that are adjacent to each other. In a plan view, the auxiliary electrode 104 is arranged between the second pixel electrode 103 and the second pixel electrode 103 that are adjacent to each other. Specifically, in a plan view, the auxiliary electrode 104 surrounds the first pixel electrode 102. In a plan view, the auxiliary electrode 104 surrounds the second pixel electrode 103. The first pixel electrode 102, the second pixel electrode 103, and the auxiliary electrode 104 are electrically isolated from one another. The auxiliary electrode 104 is also referred to as a shield electrode.

In the present embodiment, the first capacitor element 203 is a metal-insulator-metal (MIM) capacitor element. According to the MIM capacitor element, the first capacitor element 203 with high capacitance density can be realized. Note that “M” in MIM refers to at least one of a metal or a metal compound. “I” in MIM refers to an insulator, such as an oxide. In other words, MIM is a concept that encompasses metal oxide metal (MOM). That is, the first capacitor element 203, which is a MIM capacitor element, refers to a dielectric, which is an insulator that may be an oxide, held between the electrode 203a and the electrode 203b, each including at least one of a metal or a metal compound. The dielectric of the first capacitor element 203 includes, for example, a high-k material. Metal oxides are cited as examples of high-k materials. Hafnium oxide (HfO₂), zirconia (ZrO₂), and the like are cited as examples of metal oxides. In the present embodiment, the first capacitor element 203 has a trench structure. FIG. 6 is a schematic partially enlarged view of the first capacitor element 203 having a trench structure. A trench structure refers to a structure that includes a flexure. The adoption of a high-k material and a trench structure is advantageous from the perspective of ensuring the capacitance value of the first capacitor element 203. In the present embodiment, the description of the first capacitor element 203 also applies to the second capacitor element 213. Specifically, the description of the structure, material, etc. of the first capacitor element 203 is applicable to the structure, material, etc. of the second capacitor element 213. In FIG. 6, symbols in parentheses denote the second capacitor element 213 and elements included in the second capacitor element 213 according to the present embodiment.

In FIG. 6, the first capacitor element 203 includes the electrode 203a and the electrode 203b. The electrode 203a is located between the electrode 203b and the semiconductor substrate 2. The second capacitor element 213 includes the electrode 213a and the electrode 213b. The electrode 213a is located between the electrode 213b and the semiconductor substrate 2.

Hereinafter, the term “MIM hierarchy MS” may be used. The MIM hierarchy MS of the present embodiment includes the first capacitor element 203, which is a MIM capacitor element, and the second capacitor element 213, which is a MIM capacitor element. FIG. 3 illustrates the MIM hierarchy MS.

As illustrated in FIG. 3, the pixel 100 has a buffer layer 4, a sealing layer 5, a color filter 112, and a planarization layer 6. With regard to the thickness direction of the semiconductor substrate 2, the photoelectric conversion film 110 is provided above the first pixel electrode 102, the second pixel electrode 103, and the auxiliary electrode 104. The photoelectric conversion film 110, the opposing electrode 111, the buffer layer 4, the sealing layer 5, the color filter 112, and the planarization layer 6 are provided from bottom to top in this order. The color filter 112 has a transmission wavelength range corresponding to each pixel 100. The first microlens 113a and the second microlens 113b are provided above the planarization layer 6.

The first signal detection circuit 200 and the second signal detection circuit 210 are respectively provided across the interface between the semiconductor substrate 2 and the insulating layer 3. The first signal detection circuit 200 detects the potential of the capacitance of the first node FDA. It can also be said that the first signal detection circuit 200 detects the potential of the first charge accumulator FD1. The second signal detection circuit 210 detects the potential of the capacitance of the second node FDB. It can also be said that the second signal detection circuit 210 detects the potential of the second charge accumulator FD2.

The insulating layers 3 are provided with plugs 105, plugs 106, the pixel electrode hierarchy ES, the MIM hierarchy MS, and wiring layers WL. Typically, each wiring layer WL includes wires. The first pixel electrode 102 is electrically connected to the first signal detection circuit 200 through the plugs 105 and the wiring layers WL. The second pixel electrode 103 is electrically connected to the second signal detection circuit 210 through the plugs 106 and the wiring layers WL. The plugs 105 and 106 may also be referred to as contacts.

Specifically, the insulating layers 3 include an insulating layer 3a, an insulating layer 3b, an insulating layer 3c, an insulting layer 3d, an insulating layer 3e, and an insulating layer 3f. The insulating layer 3a, the insulating layer 3b, the insulating layer 3c, the insulating layer 3d, the insulating layer 3e, and the insulating layer 3f are each provided with at least one plug 105 and at least one plug 106. The insulating layer 3a, the insulating layer 3b, the insulating layer 3c, the insulating layer 3d, and the insulating layer 3e are each provided with at least one wiring layer WL.

More specifically, the plugs 105 include via plugs 105v and a contact plug 105c. The plugs 106 include via plugs 106v and a contact plug 106c. The wiring layers WL include a gate wiring layer WLG, a first wiring layer WL1, a second wiring layer WL2, a third wiring layer WL3, a fourth wiring layer WL4, a fifth wiring layer WL5, and a sixth wiring layer WL6.

The wiring layers 3 are each configured as below:
the insulating layer 3a is provided with the gate wiring layer WLG, the contact plug 105c, the contact plug 106c, the first wiring layer WL1, the via plug 105v, the via plug 106v, the second wiring layer WL2, and the MIM hierarchy MS;
the insulating layer 3b is provided with the via plug 105v, the via plug 106v, and the third wiring layer WL3;
the insulating layer 3c is provided with the via plug 105v, the via plug 106v, and the fourth wiring layer WL4;
the insulating layer 3d is provided with the via plug 105v, the via plug 106v, and the fifth wiring layer WL5;
the insulating layer 3e is provided with the via plug 105v, the via plug 106v, and the sixth wiring layer WL6; and
the insulating layer 3f is provided with the via plug 105v, the via plug 106v, and the pixel electrode hierarchy ES.

A first transmission path 125 is configured including the contact plug 105c, the first wiring layer WL1, the via plug 105v of the insulating layer 3a, the second wiring layer WL2, the via plug 105v of the insulating layer 3b, the third wiring layer WL3, the via plug 105v of the insulating layer 3c, the fourth wiring layer WL4, the via plug 105v of the insulating layer 3d, the fifth wiring layer WL5, the via plug 105v of the insulating layer 3e,
the sixth wiring layer WL6, and the via plug 105v of the insulating layer 3f in this order. The first pixel electrode 102 is electrically connected to the first charge accumulator FD1 through the first transmission path 125. A portion of the charge generated by the photoelectric conversion film 110 is collected as the first signal charge by the first pixel electrode 102. The first signal charge is transmitted from the first pixel electrode 102 to the first charge accumulator FD1 through the first transmission path 125.

A second transmission path 135 is configured including the contact plug 106c, the first wiring layer WL1, the via plug 106v of the insulating layer 3a, the second wiring layer WL2, the via plug 106v of the insulating layer 3b, the third wiring layer WL3, the via plug 106v of the insulating layer 3c, the fourth wiring layer WL4, the via plug 106v of the insulating layer 3d, the fifth wiring layer WL5, the via plug 106v of the insulating layer 3e, the sixth wiring layer WL6, and the via plug 106v of the insulating layer 3f in this order. The second pixel electrode 103 is electrically connected to the second charge accumulator FD2 through the second transmission path 135. A portion of the charge generated by the photoelectric conversion film 110 is collected as the second signal charge by the second pixel electrode 103. The second signal charge is transmitted from the second pixel electrode 103 to the second charge accumulator FD2 through the second transmission path 135.

A portion of the charge generated by the photoelectric conversion film 110 is collected by the auxiliary electrode 104. This reduces the likelihood of the charge that should be collected by a given first pixel electrode 102 being collected by an adjacent first pixel electrode 102. This reduces the likelihood of the charge that should be collected by a given second pixel electrode 103 being collected by an adjacent second pixel electrode 103. Additionally, this reduces the likelihood of the charge that should be collected by a given first pixel electrode 102 being collected by an adjacent second pixel electrode 103, and the likelihood of the charge that should be collected by a given second pixel electrode 103 being collected by an adjacent first pixel electrode 102. This enables the suppression of noise such as color mixing between adjacent pixels. Specifically, the auxiliary electrode 104 is connected, for example, to a voltage supply circuit or ground, which is not illustrated in the figure, and is maintained at a predetermined potential. In the case of using holes as signal charge, setting the potential of the auxiliary electrode 104 lower than that of the opposing electrode 111 allows the signal charge to be attracted to the auxiliary electrode 104. The potential of the auxiliary electrode 104 is a fixed potential in the present embodiment, but it may be a fluctuating potential.

In the example illustrated in FIG. 3, the specific capacitor element 204 is configured using the fourth wiring layer WL4 and the fifth wiring layer WL5. Specifically, the specific capacitor element 204 includes the predetermined electrode 204a, the specific electrode 204b, and a dielectric located between the predetermined electrode 204a and the specific electrode 204b. The predetermined electrode 204a includes wires electrically connected to the first node FDA. Specifically, the predetermined electrode 204a may be wires included in the first transmission path 125. The specific electrode 204b includes wires electrically connected to the specific node RD. The dielectric includes a portion of the insulating layers 3.

In FIG. 3, one of the source and drain of the first reset transistor 202 is a diffusion layer that constitutes the first charge accumulator FD1, and the other is a diffusion layer DL1. The diffusion layer DL1 is electrically connected to the electrode 203a of the first capacitor element 203 through the first wiring layer WL1. The diffusion layer DL1 and the electrode 203a are electrically connected to the specific node RD. Additionally, one of the source and drain of the second reset transistor 217 is a diffusion layer that constitutes the second charge accumulator FD2, and the other is a diffusion layer DL2.

A portion of the insulating layer 3f is interposed between the first pixel electrode 102, the second pixel electrode 103, and the auxiliary electrode 104 that are adjacent to each other. The first pixel electrode 102, the second pixel electrode 103, and the auxiliary electrode 104 each have a uniform film thickness and a planarized top surface.

The photoelectric conversion film 110 is composed of a photoelectric conversion material that generates charge according to the intensity of received light. The photoelectric conversion material may include at least one of an organic material or an inorganic material. The organic material may be an organic semiconductor material. The organic semiconductor material may include at least one of p-type organic semiconductor or n-type organic semiconductor. The inorganic material is, for example, amorphous silicon. The photoelectric conversion film 110 may be a mixed film of organic donor molecules and acceptor molecules, a mixed film of semiconductor carbon nanotubes and acceptor molecules, a quantum dot-containing film, or the like. The photoelectric conversion film 110 may be a metal oxide film. The metal oxide film is, for example, a copper oxide (CuO) film. These descriptions of the materials of the photoelectric conversion film 110 are applicable to the first photoelectric conversion film 110a and the second photoelectric conversion film 110b.

The opposing electrode 111 may include a transparent conductive material. The transparent conductive material is, for example, a transparent oxide conductive material. The transparent oxide conductive material is, for example, indium tin oxide (ITO), indium zinc oxide (IZO), or the like. These descriptions of the materials of the opposing electrode 111 are applicable to the first opposing electrode 111a and the second opposing electrode 111b.

The first pixel electrode 102 may include at least one of a metal material or a metal compound material. The metal material is, for example, copper (Cu), tungsten (W), titanium (Ti), tantalum (Ta), aluminum (Al), or the like. The metal compound material is, for example, a compound of the metal materials listed above. The metal compound material may be a metal nitride. The metal nitride is, for example, titanium nitride (TiN). These descriptions of the materials of the first pixel electrode 102 are applicable to the second pixel electrode 103 and the auxiliary electrode 104.

The via plugs 105v may include a conductive material. The conductive material is, for example, copper (Cu), tungsten (W), or the like. The via plugs 105v may be formed by embedding a conductive material into the insulating layers 3. These descriptions of the materials of the via plugs 105v are applicable to the via plugs 106v. The same descriptions are applicable to other via plugs, such as later-described via plugs vp1a, vp1b, vp1c, vp1d, vp1e, vp1f, vp1g, vp1h, vp1i, vp1j, vp1k, vp1m, vp1n, vp1p, vp1q, vp1r, vp2a, vp2b, vp2c, vp2d, vp2c, vp2f, vp2g, vp2h, vp2i, vp2j, vp2k, vp2m, vp2n, vp2s, vp2t, vp3a, vp3b, vp3d, vp3c, vp3h, vp3j, vp3s, vp3t, vp4a, vp4b, vp4d, vp4c, vp5a, vp5d, vp6a, vp6d, and the like.

Wires included in the wiring layers WL may include a conductive material. The conductive material is, for example, copper (Cu), tungsten (W), or the like. In this context, the wires included in the wiring layers WL may be at least one of a first wire, a second wire, a first signal wire, a second signal wire, or wires, which will be described later.

The contact plug 105c may be polysilicon doped with impurities. The impurities are phosphorus, boron, or the like. The contact plug 105c may be formed by embedding such a material into the insulating layers 3. These descriptions of the materials of the contact plug 105c are applicable to the contact plug 106c. The same descriptions are applicable to other contact plugs such as later-described contact plugs cpa1, cpa2, cpa3, cpb, cpc, cpd1, cpd2, cpe1, cpe2, cpe3, cpe4, cpf, cpg, cph, cpi, cpj, cpk, cpp, cpq, cpr, and the like.

The first charge accumulator FD1 may have impurities of the same conductivity type as the impurities of the contact plug 105c. The second charge accumulator FD2 may have impurities of the same conductivity type as the impurities of the contact plug 106c.

The semiconductor substrate 2 includes, for example, silicon (Si) or the like. The insulating layers 3 include, for example, silicon dioxide (SiO₂) or the like. The insulating layer 3a, insulating layer 3b, insulating layer 3c, insulating layer 3d, insulating layer 3e, and insulating layer 3f include, for example, silicon dioxide.

Note that the number of insulating layers 3 can be set arbitrarily, and is not limited to six layers illustrated in FIG. 3. The same applies to the number of wiring layers WL.

The first cells 100a may have a configuration different from the configuration illustrated in FIG. 2. The second cells 100b may have a configuration different from the configuration illustrated in FIG. 2.

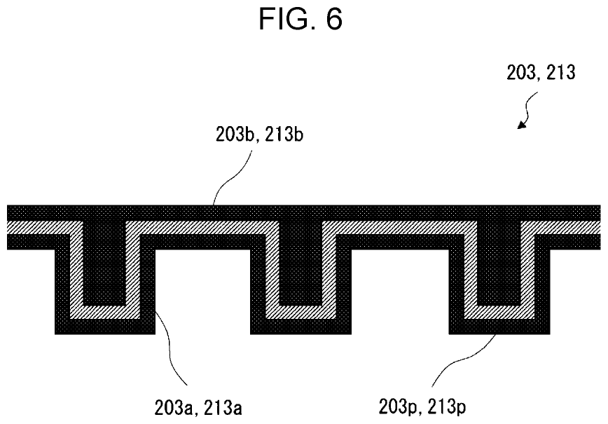

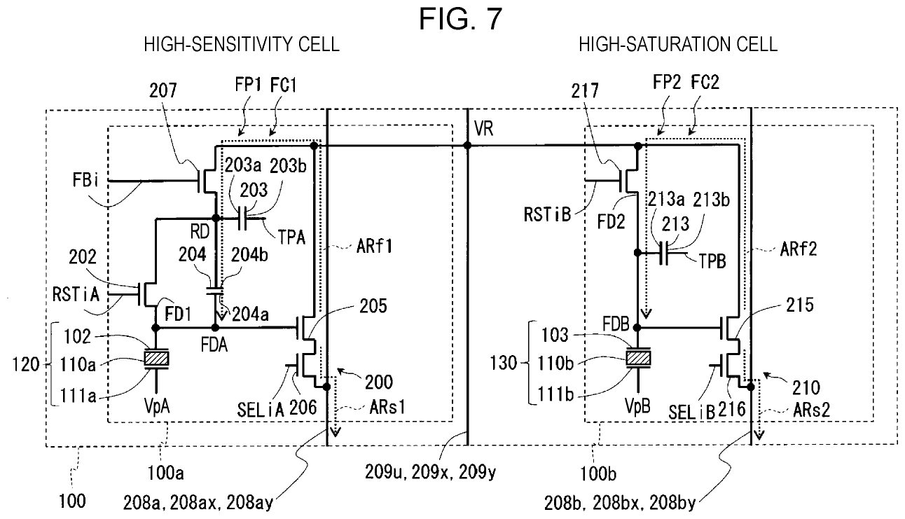

FIG. 7 is a circuit diagram of a pixel 100 according to another example of the embodiment.

In the configuration illustrated in FIG. 7, a power supply wire 209u is shared by both the first cell 100a and the second cell 100b.

In the configuration illustrated in FIG. 7, the power supply wire 209u is electrically connected to the power supply node VR. The power supply node VR is electrically connected to one of the source and drain of the band control transistor 207, to the other of the source and drain of the second reset transistor 217, to the other of the source and drain of the first amplifier transistor 205, and to the other of the source and drain of the second amplifier transistor 215.

During a signal readout period, the power supply potential VDD is applied to the other of the source and drain of the first amplifier transistor 205 through the power supply wire 209u. In this potential applied state, as schematically indicated by dotted-line arrow ARs1, the first electric signal output from the terminal on the first selection transistor 206 side, of the source and drain of the first amplifier transistor 205, flows through the first selection transistor 206 and the first vertical signal line 208a in this order. In this way, the first electric signal based on the first signal charge generated by the first photoelectric converter 120 is read out.

During the signal readout period, the power supply potential VDD is applied to the other of the source and drain of the second amplifier transistor 215 through the power supply wire 209u. In this potential applied state, as schematically indicated by dotted-line arrow ARs2, the second electric signal output from the terminal on the second selection transistor 216 side, of the source and drain of the second amplifier transistor 215, flows through the second selection transistor 216 and the second vertical signal line 208b in this order. In this way, the second electric signal based on the second signal charge generated by the second photoelectric converter 130 is read out.

During a feedback period, as schematically indicated by dotted-line arrow ARf1, the first electric signal output from the terminal opposite the first selection transistor 206, of the source and drain of the first amplifier transistor 205, is negatively fed back to the capacitance of the first node FDA through the band control transistor 207 and the specific capacitor element 204 in this order. This causes kTC noise, generated when turning off the first reset transistor 202, to be negatively fed back to the capacitance of the first node FDA.

During the feedback period, as schematically indicated by dotted-line arrow ARf2, the second electric signal output from, of the source and drain of the second amplifier transistor 215, the terminal opposite the second selection transistor 216 is negatively fed back to the capacitance of the second node FDB through the second reset transistor 217. This causes kTC noise, generated when turning off the second reset transistor 217, to be negatively fed back to the capacitance of the second node FDB.

Note that, in the circuit illustrated in FIG. 7, the configuration for realizing the signal readout period and the feedback period is not particularly limited. For example, the signal readout period and the feedback period can be realized by switching a control potential or the like applied to the pixel 100. Specifically, by switching a control potential or the like applied to the pixel 100, it is possible for the first cell 100a to switch between reading out the signal as indicated by dotted-line arrow ARs1 and performing negative feedback of the signal as indicated by dotted-line arrow ARf1. Additionally, by switching a control potential or the like applied to the pixel 100, it is possible for the second cell 100b to switch between reading out the signal as indicated by dotted-line arrow ARs2 and performing negative feedback of the signal as indicated by dotted-line arrow ARf2. See Japanese Patent Nos. 6323813 and 6782431, for example, for switching a control potential or the like applied to the pixel 100.

There are two types of the power supply wire 209u. The first type of the power supply wire 209u is labeled as a power supply wire 209x, and the second type of the power supply wire 209u is labeled as a power supply wire 209y. The power supply wire 209x is electrically connected to the first cell 100a and the second cell 100b of the pixels 100 in either the odd rows or the even rows. The power supply wire 209y is electrically connected to the first cell 100a and the second cell 100b of the pixels 100 in the other of the odd rows and the even rows. The power supply wire 209x and the power supply wire 209y are both wires to which the power supply potential VDD may be applied, but they are electrically isolated from each other.

In the configuration illustrated in FIG. 7, there are two types of the first vertical signal line 208a. The first type of the first vertical signal line 208a is labeled as a first vertical signal line 208ax, and the second type of the first vertical signal line 208a is labeled as a first vertical signal line 208ay. The first vertical signal line 208ax is electrically connected to the first cell 100a of the pixels 100 in either the odd rows or the even rows. The first vertical signal line 208ay is electrically connected to the first cell 100a of the pixels 100 in the other of the odd rows and the even rows. The first vertical signal line 208ax and the first vertical signal line 208ay are both wires through which the first electric signal may flow, but they are electrically isolated from each other.

In the configuration illustrated in FIG. 7, there are two types of the second vertical signal line 208b. The first type of the second vertical signal line 208b is labeled as a second vertical signal line 208bx, and the second type of the second vertical signal line 208b is labeled as a second vertical signal line 208by. The second vertical signal line 208bx is electrically connected to the second cell 100b of the pixels 100 in either the odd rows or the even rows. The second vertical signal line 208by is electrically connected to the second cell 100b of the pixels 100 in the other of the odd rows and the even rows. The second vertical signal line 208bx and the second vertical signal line 208by are both wires through which the second electric signal may flow, but they are electrically isolated from each other.

In the configuration illustrated in FIG. 7, for the first cell 100a of the pixels 100 in either the odd rows or the even rows, the supply of the power supply potential VDD to the first amplifier transistor 205 is performed through the power supply wire 209x, and the first electric signal from the first amplifier transistor 205 is output to the first vertical signal line 208ax. For the first cell 100a of the pixels 100 in the other of the odd rows and the even rows, the supply of the power supply potential VDD to the first amplifier transistor 205 is performed through the power supply wire 209y, and the first electric signal from the first amplifier transistor 205 is output to the first vertical signal line 208ay. For the second cell 100b of the pixels 100 in either the odd rows or the even rows, the supply of the power supply potential VDD to the second amplifier transistor 215 is performed through the power supply wire 209x, and the second electric signal from the second amplifier transistor 215 is output to the second vertical signal line 208bx. For the second cell 100b of the pixels 100 in the other of the odd rows and the even rows, the supply of the power supply potential VDD to the second amplifier transistor 215 is performed through the power supply wire 209y, and the second electric signal from the second amplifier transistor 215 is output to the second vertical signal line 208by.

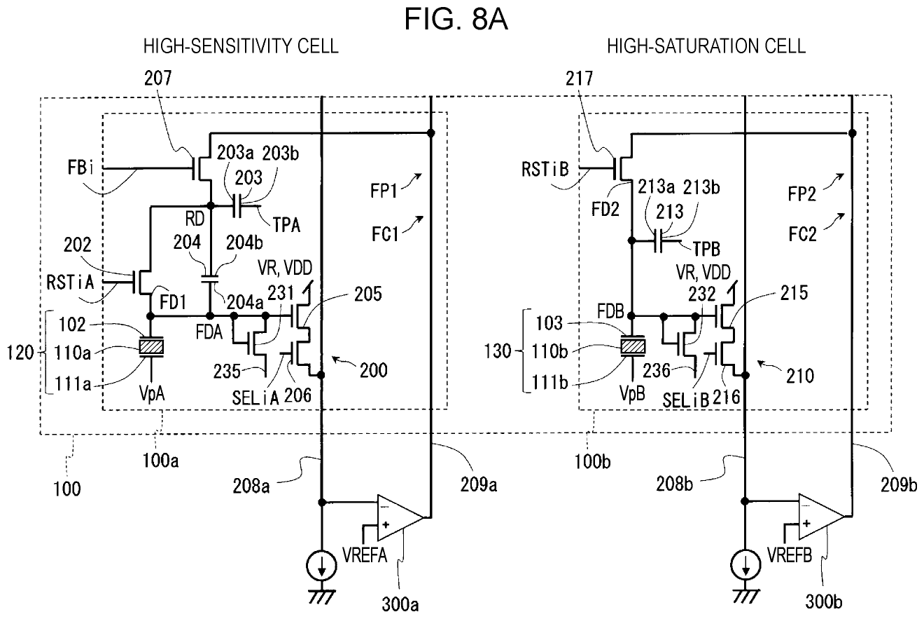

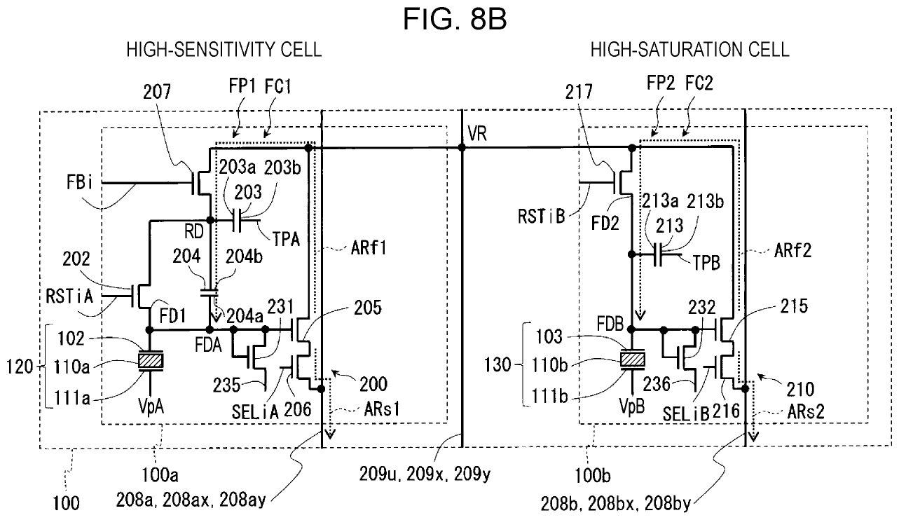

The pixel 100 in FIG. 2 or FIG. 7 may be modified so that:
the first cell 100a includes a first overflow transistor 231; and
the second cell 100b includes a second overflow transistor 232.
   FIG. 8A is a circuit diagram in which overflow transistors are applied to the circuit diagram of FIG. 2. FIG. 8B is a circuit diagram in which overflow transistors are applied to the circuit diagram of FIG. 7.

In FIGS. 8A and 8B, in the first cell 100a, the gate of the first overflow transistor 231 and one of the source and drain of the first overflow transistor 231 are electrically connected to the first node FDA. The other of the source and drain of the first overflow transistor 231 is electrically connected to a first discharge line 235.

The first overflow transistor 231 turns on when the potential of the first node FDA reaches a first threshold potential. In response to the turning on, excess charge accumulated in the capacitance of the first node FDA is discharged to the first discharge line 235 through the first overflow transistor 231 This prevents malfunctions such as burn-in of the first cell 100a.

In FIGS. 8A and 8B, in the second cell 100b, the gate of the second overflow transistor 232 and one of the source and drain of the second overflow transistor 232 are electrically connected to the second node FDB. The other of the source and drain of the second overflow transistor 232 is electrically connected to a second discharge line 236.

The second overflow transistor 232 turns on when the potential of the second node FDB reaches a second threshold potential. In response to the turning on, excess charge accumulated in the capacitance of the second node FDB is discharged to the second discharge line 236 through the second overflow transistor 232. This prevents malfunctions such as burn-in of the second cell 100b.

The first overflow transistor 231 and the first reset transistor 202 may share the first charge accumulator FD1. The second overflow transistor 232 and the second reset transistor 217 may share the second charge accumulator FD2. The first cell 100a may have the first overflow transistor 231, and the second cell 100b may not have the second overflow transistor 232. The first cell 100a may not have the first overflow transistor 231, and the second cell 100b may have the second overflow transistor 232.

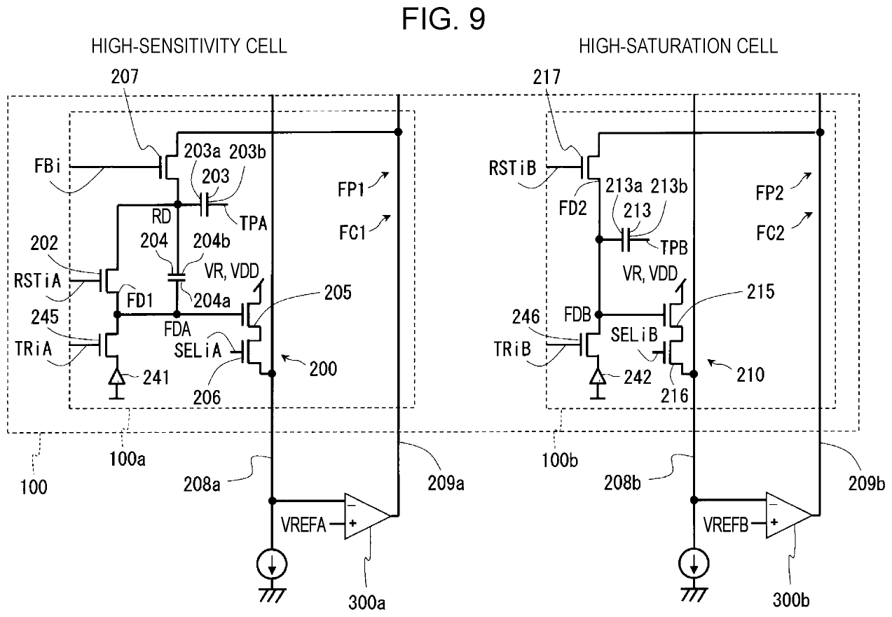

The pixel 100 in FIG. 2, 7, 8A, or 8B may be modified so that:
the first cell 100a includes a first photoelectric converter 241 instead of the first photoelectric converter 120;
the first cell 100a includes a first transfer transistor 245 interposed between the first photoelectric converter 241 and the first charge accumulator FD1;
the second cell 100b includes a second photoelectric converter 242 instead of the second photoelectric converter 130; and
the second cell 100b includes a second transfer transistor 246 interposed between the second photoelectric converter 242 and the second charge accumulator FD2. Here, the first photoelectric converter 241 and the second photoelectric converter 242 are respectively photodiodes. The first photoelectric converter 241 and the second photoelectric converter 242 are provided on the semiconductor substrate 2. FIG. 9 is a diagram of a circuit configuration using photoelectric converters, which are photodiodes. Specifically, FIG. 9 illustrates a circuit configuration obtained by applying the modification to the circuit configuration illustrated in FIG. 2.

In FIG. 9, in the first cell 100a, the first photoelectric converter 241 and the first charge accumulator FD1 are connected through the first transfer transistor 245. In response to turning on of the first transfer transistor 245, the first signal charge is transferred from the first photoelectric converter 241 to the first charge accumulator FD1. In the second cell 100b, the second photoelectric converter 242 and the second charge accumulator FD2 are connected through the second transfer transistor 246. In response to turning on of the second transfer transistor 246, the second signal charge is transferred from the second photoelectric converter 242 to the second charge accumulator FD2.

The first transfer transistor 245 and the first reset transistor 202 may share the first charge accumulator FD1. The second transfer transistor 246 and the second reset transistor 217 may share the second charge accumulator FD2.

The configuration at each layer of the imaging device 1 will be described with reference to FIGS. 10A to 10I below:
FIG. 10A is a schematic configuration diagram of the gate wiring layer WLG in plan view;
FIG. 10B is a schematic configuration diagram of the first wiring layer WL1 in plan view;
FIG. 10C is a schematic configuration diagram of the MIM hierarchy MS in plan view;
FIG. 10D is a schematic configuration diagram of the second wiring layer WL2 in plan view;
FIG. 10E is a schematic configuration diagram of the third wiring layer WL3 in plan view;
FIG. 10F is a schematic configuration diagram of the fourth wiring layer WL4 in plan view;
FIG. 10G is a schematic configuration diagram of the fifth wiring layer WL5 in plan view;
FIG. 10H is a schematic configuration diagram of the sixth wiring layer WL6 in plan view; and
FIG. 10I is a schematic configuration diagram of the pixel electrode hierarchy ES in plan view.

Note that the configurations illustrated in FIGS. 10A to 10I correspond to the configuration illustrated in FIG. 7. However, unless otherwise contradicted, some or all of the configurations illustrated in FIGS. 10A to 10I may be combined with the configuration illustrated in FIG. 2, may be combined with the configuration illustrated in FIG. 8A, may be combined with the configuration illustrated in FIG. 8B, or may be combined with the configuration illustrated in FIG. 9.

In FIG. 10A for the gate wiring layer WLG,
a gate 202g is the gate of the first reset transistor 202;
a gate 217g is the gate of the second reset transistor 217;
a gate 205g is the gate of the first amplifier transistor 205;
a gate 215g is the gate of the second amplifier transistor 215;
a gate 206g is the gate of the first selection transistor 206;
a gate 216g is the gate of the second selection transistor 216; and
a gate 207g is the gate of the band control transistor 207.

In the present embodiment, the gate 202g, gate 217g, gate 205g, gate 215g, gate 206g, and gate 216g are made of N-type polysilicon.

Control signals supplied to the gates will be described as below:
turning on/off of the first reset transistor 202 is controlled by supplying a first reset control signal from the row scanning circuit 310 to the gate 202g through the first reset control line RSTiA;
turning on/off of the second reset transistor 217 is controlled by supplying a second reset control signal from the row scanning circuit 310 to the gate 217g through the second reset control line RSTiB;
turning on/off of the first selection transistor 206 is controlled by supplying a first selection control signal from the row scanning circuit 310 to the gate 206g through the first address control line SELiA;
turning on/off of the second selection transistor 216 is controlled by supplying a second selection control signal from the row scanning circuit 310 to the gate 216g through the second address control line SELiB; and
turning on/off of the band control transistor 207 is controlled by supplying a band control signal from the row scanning circuit 310 to the gate 207g through the feedback control line FBi.
   These control signals are potential signals.

Note that, in the example illustrated in FIG. 9,
turning on/off of the first transfer transistor 245 is controlled by supplying a first transfer control signal from the row scanning circuit 310 to the gate of the first transfer transistor 245 through the first transfer control line TRIA; and
turning on/off of the second transfer transistor 246 is controlled by supplying a second transfer control signal from the row scanning circuit 310 to the gate of the second transfer transistor 246 through the second transfer control line TRIB.
   These control signals are potential signals.

FIG. 10A also depicts diffusion layers located within the semiconductor substrate 2. In FIG. 10A,
the first charge accumulator FD1 is a diffusion layer that is either the source or drain of the first reset transistor 202;
the diffusion layer DL1 is a diffusion layer that serves as both the other of the source and drain of the first reset transistor 202 and one of the source and drain of the band control transistor 207;
the second charge accumulator FD2 is a diffusion layer that is either the source or drain of the second reset transistor 217;
the diffusion layer DL2 is a diffusion layer that is the other of the source and drain of the second reset transistor 217;
a diffusion layer DL3 is a diffusion layer that is the other of the source and drain of the band control transistor 207;
a diffusion layer DLA is a diffusion layer that serves as both one of the source and drain of the first amplifier transistor 205 and one of the source and drain of the first selection transistor 206;
a diffusion layer DL5 is a diffusion layer that is the other of the source and drain of the first selection transistor 206;
a diffusion layer DL6 is a diffusion layer that serves as both one of the source and drain of the second amplifier transistor 215 and one of the source and drain of the second selection transistor 216;
a diffusion layer DL7 is a diffusion layer that is the other of the source and drain of the second selection transistor 216; and
a diffusion layer DL8 is a diffusion layer that serves as both the other of the source and drain of the first amplifier transistor 205 and the other of the source and drain of the second amplifier transistor 215.

As illustrated in FIG. 10B, the first wiring layer WL1 includes a wire W1a, a wire W1b, a wire Wc, a wire W1d, a wire W1e, a wire W1f, a wire W1g, a wire W1h, a wire W1i, a wire W1j, and a wire W1k.

FIG. 10A additionally depicts contact plugs (hereinafter may simply be referred to as plugs) cpa1, cpa2, cpb, cpc, cpd1, cpd2, cpe1, cpe2, cpe3, cpe4, cpf, cpg, cph, cpi, cpj and cpk.

As understood from FIG. 10A for the gate wiring layer WLG and FIG. 10B for the first wiring layer WL1,
the plug cpa1 electrically connects the first charge accumulator FD1 and the wire W1a;
the plug cpa2 electrically connects the gate 205g and the wire W1a;
the plug cpb electrically connects the diffusion layer DL1 and the wire W1b;
the plug cpc electrically connects the gate 202g and the wire W1c;
the plug cpd1 electrically connects the second charge accumulator FD2 and the wire W1d;
the plug cpd2 electrically connects the gate 215g and the wire W1d;
the plug cpe1 electrically connects the diffusion layer DL2 and the wire W1e;
the plug cpe2 electrically connects the diffusion layer DL3 and the wire W1e;
the plugs cpe3 and cpe4 electrically connect to the diffusion layer DL8 and the wire W1e;
the plug cpf electrically connects the gate 217g and the wire W1f;
the plug cpg electrically connects the gate 207g and the wire W1g;
the plug cph electrically connects the diffusion layer DL5 and the wire W1h;
the plug cpi electrically connects the gate 206g and the wire W1i;
the plug cpj electrically connects the diffusion layer DL7 and the wire W1j; and
the plug cpk electrically connects the gate 216g and the wire W1k.

The contact plug cpa1 is the contact plug 105c. The contact plug cpd1 is the contact plug 106c.

As mentioned earlier, the first capacitor element 203 includes the electrode 203a, which is on the side closer to the semiconductor substrate 2, and the electrode 203b, which is on the side farther from the semiconductor substrate 2. The second capacitor element 213 includes the electrode 213a, which is on the side closer to the semiconductor substrate 2, and the electrode 213b, which is on the side farther from the semiconductor substrate 2. In FIG. 10C, the electrode 203b and the electrode 213b are indicated by hatching. As mentioned earlier, in the present embodiment, the first capacitor element 203 and the second capacitor element 213 have a trench structure. The electrode 203a has protrusions 203p protruding toward the semiconductor substrate 2 side, derived from a trench structure. The electrode 213a has protrusions 213p protruding toward the semiconductor substrate 2 side, derived from a trench structure. In FIG. 10C, the protrusions 203p and the protrusions 213p are indicated by dotted lines.

FIG. 10B also depicts via plugs (hereinafter may simply be referred to as plugs) vp1m, vp1n, vp1a, vp1b, vp1c, vp1d, vp1e, vp1f, vp1g, vp1h, vp1i, vp1j, and vp1k.

As understood from FIG. 10B for the first wiring layer WL1 and FIG. 10C for the MIM hierarchy MS,
the plug vp1m electrically connects the wire W1b and the protrusion 203p; and
the plug vp1n electrically connects the wire W1d and the protrusion 213p.

Note that, in FIG. 10C, the position of the plug vp1m and the position of the plug vp1n are indicated by dotted leader lines. The plug vp1m electrically connects the electrode 203a to the specific node RD. The plug vp1n electrically connects the electrode 213a to the second node FDB.

As illustrated in FIG. 10D, the second wiring layer WL2 includes a wire W2a, a wire W2b, a wire W2c, a wire W2d, a wire W2e, a wire W2f, a wire W2g, a wire W2h, a wire W2i, a wire W2j, a wire W2k, a wire W2s, and a wire W2t.

As understood from FIG. 10B for the first wiring layer WL1 and FIG. 10D for the second wiring layer WL2,
the plug vp1a electrically connects the wire W1a and the wire W2a;
the plug vp1b electrically connects the wire W1b and the wire W2b;
the plug vp1c electrically connects the wire W1c and the wire W2c;
the plug vp1d electrically connects the wire W1d and the wire W2d;
the plug vp1e electrically connects the wire W1e and the wire W2e;
the plug vp1f electrically connects the wire W1f and the wire W2f;
the plug vp1g electrically connects the wire W1g and the wire W2g;
the plug vp1h electrically connects the wire W1h and the wire W2h;
the plug vp1i electrically connects the wire W1i and the wire W2i;
the plug vp1j electrically connects the wire W1j and the wire W2j; and
the plug vp1k electrically connects the wire W1k and the wire W2k.

The via plug vp1a is the via plug 105v. The via plug vp1d is the via plug 106v.

FIG. 10D also depicts via plugs (hereinafter may simply be referred to as plugs) vp2m, vp2n, vp2a, vp2b, vp2c, vp2d, vp2e, vp2f, vp2g, vp2h, vp2i, vp2j, vp2k, vp2s, and vp2t.

As understood from FIG. 10D for the second wiring layer WL2 and FIG. 10C for the MIM hierarchy MS,
the plug vp2m electrically connects to the wire W2m and the electrode 203b; and
the plug vp2n electrically connects to the wire W2n and the electrode 213b.

As illustrated in FIG. 10E, the third wiring layer WL3 includes a wire W3a, a wire W3b, a wire W3c, a wire W3d, a wire W3e, a wire W3h, a wire W3i, a wire W3j, a wire W3s, a wire W3t, the first reset control line RSTiA, the second reset control line RSTiB, the feedback control line FBi, the first address control line SELiA, and the second address control line SELiB. Note that, as mentioned earlier, the first reset control line RSTiA is provided corresponding to each row of the pixel array 10. FIG. 10E illustrates the first reset control line RSTiA for two rows.

As understood from FIG. 10D for the second wiring layer WL2 and FIG. 10E for the third wiring layer WL3,
the plug vp2a electrically connects the wire W2a and the wire W3a;
the plug vp2b electrically connects the wire W2b and the wire W3b;
the plug vp2c electrically connects the wire W2c and the wire W3c;
the plug vp2d electrically connects the wire W2d and the wire W3d;
the plug vp2e electrically connects the wire W2e and the wire W3e;
the plug vp2f electrically connects the wire W2f and the second reset control line RSTiB;
the plug vp2g electrically connects the wire W2g and the feedback control line FBi;
the plug vp2h electrically connects the wire W2h and the wire W3h;
the plug vp2i electrically connects the wire W2i and the wire W3i;
the plug vp2j electrically connects the wire W2j and the wire W3j;
the plug vp2k electrically connects the wire W2k and the second address control line SELiB;
the plug vp2s electrically connects the wire W2s and the wire W3s; and
the plug vp2t electrically connects the wire W2t and the wire W3t.

The via plug vp2a is the via plug 105v. The via plug vp2d is the via plug 106v. The wire W3c is electrically connected to the first reset control line RSTiA. The wire W3i is electrically connected to the first address control line SELiA.

FIG. 10E also depicts via plugs (hereinafter may simply be referred to as plugs) vp3a, vp3b, vp3d, vp3e, vp3h, vp3j, vp3s, and vp3t.

As illustrated in FIG. 10F, the fourth wiring layer WL4 includes a wire W4a, a wire W4b, a wire W4d, a wire W4e, the first vertical signal line 208ax, the first vertical signal line 208ay, the second vertical signal line 208bx, the second vertical signal line 208by, the first capacitance control line TPA, and the second capacitance control line TPB.

As understood from FIG. 10E for the third wiring layer WL3 and FIG. 10F for the fourth wiring layer WL4,
the plug vp3a electrically connects the wire W3a and the wire W4a;
the plug vp3b electrically connects the wire W3b and the wire W4b;
the plug vp3d electrically connects the wire W3d and the wire W4d,
the plug vp3e electrically connects the wire W3e and the wire W4e;
the plug vp3h electrically connects the wire W3h and the first vertical signal line 208ax;
the plug vp3j electrically connects the wire W3j and the second vertical signal line 208bx;
the plug vp3s electrically connects the wire W3s and the first capacitance control line TPA; and
the plug vp3t electrically connects the wire W3t and the second capacitance control line TPB.

The via plug vp3a is the via plug 105v. The via plug vp3d is the via plug 106v.

The position of the via plug vp3h differs between the pixels 100 in the odd rows and the pixels 100 in the even rows. Specifically, the position of the via plug vp3h in FIG. 10E is a position in the pixels 100 in either the odd rows or the even rows, and is a position that electrically connects the wire W3h to the first vertical signal line 208ax. The via plug vp3h electrically connects the wire W3h to the first vertical signal line 208ay in the pixels 100 in the other of the odd rows and the even rows by being located to the right as indicated by a dotted line, compared to FIG. 10E.

The position of the via plug vp3j differs between the pixels 100 in the odd rows and the pixels 100 in the even rows. Specifically, the position of the via plug vp3j in FIG. 10E is a position in the pixels 100 in either the odd rows or the even rows, and is a position that electrically connects the wire W3j to the second vertical signal line 208bx. The via plug vp3j electrically connects the wire W3j to the second vertical signal line 208by in the pixels 100 in the other of the odd rows and the even rows by being located to the right as indicated by a dotted line, compared to FIG. 10E.

FIG. 10F also depicts via plugs (hereinafter may simply be referred to as plugs) vp4a, vp4b, vp4d, and vp4e.

As illustrated in FIG. 10G, the fifth wiring layer WL5 includes a wire W5a, a wire W5b, a wire W5d, a wire W5e, the power supply wire 209x, and the power supply wire 209y.

As understood from FIG. 10F for the fourth wiring layer WL4 and FIG. 10G for the fifth wiring layer WL5,
the plug vp4a electrically connects the wire W4a and the wire W5a;
the plug vp4b electrically connects the wire W4b and the wire W5b;
the plug vp4d electrically connects the wire W4d and the wire W5d; and
the plug vp4e electrically connects the wire W4e and the wire W5e.

The via plug vp4a is the via plug 105v. The via plug vp4d is the via plug 106v. The wire W5e is electrically connected to the power supply wire 209x.

The position of the wire W5e differs between the pixels 100 in the odd rows and the pixels 100 in the even rows. Specifically, the position of the wire W5e in FIG. 10G is a position in the pixels 100 in either the odd rows or the even rows, and is a position that electrically connects the plug vp4e to the power supply wire 209x. The wire W5e electrically connects the plug vp4e to the power supply wire 209y in the pixels 100 in the other of the odd rows and the even rows by being located to the right as indicated by a dotted line, compared to FIG. 10G.

As understood from FIGS. 10F and 10G, the specific capacitor element 204 is configured across the third wiring layer WL3 and the fourth wiring layer WL4. Specifically, the predetermined electrode 204a includes the wire W4a and the wire W5a. The specific electrode 204b includes the wire W4b and the wire W5b. A dielectric of the specific capacitor element 204 is located between the predetermined electrode 204a and the specific electrode 204b. The dielectric includes, among the insulating layers 3, portions located in the third wiring layer WL3 and the fourth wiring layer WL4.

FIG. 10G also depicts via plugs (hereinafter may simply be referred to as plugs) vp5a and vp5d.

As illustrated in FIG. 10H, the sixth wiring layer WL6 includes a wire W6a and a wire W6d.

As understood from FIG. 10G for the fifth wiring layer WL5 and FIG. 10H for the sixth wiring layer WL6,
the plug vp5a electrically connects the wire W5a and the wire W6a; and
the plug vp5d electrically connects the wire W5d and the wire W6d.

The via plug vp5a is the via plug 105v. The via plug vp5d is the via plug 106v.

FIG. 10H also depicts via plugs (hereinafter may simply be referred to as plugs) vp6a and vp6d. As illustrated in FIG. 10I, the pixel electrode hierarchy ES includes the first pixel electrode 102, the second pixel electrode 103, and the auxiliary electrode 104.

As understood from FIGS. 10H and 10I for the sixth wiring layer WL6,
the plug vp6a electrically connects the wire W6a and the first pixel electrode 102; and
the plug vp6d electrically connects the wire W6d and the second pixel electrode 103.

The via plug vp6a is the via plug 105v. The via plug vp6d is the via plug 106v.

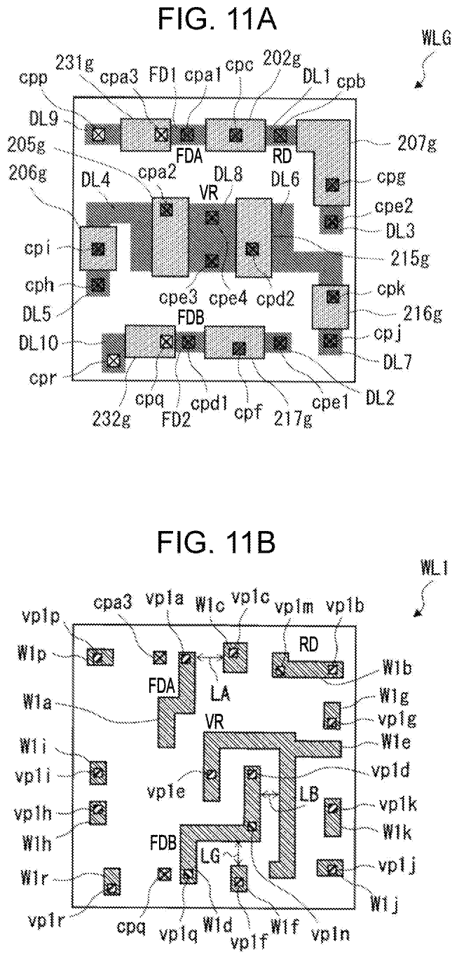

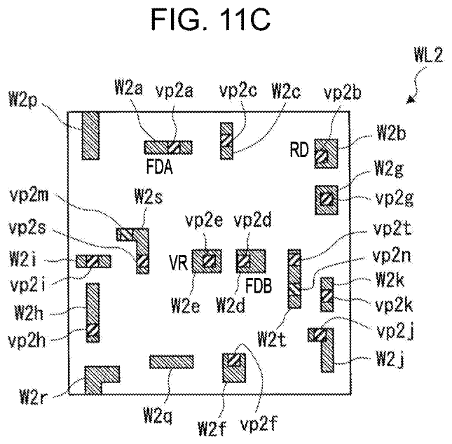

With reference to FIGS. 11A to 11C as described below, the configuration at each layer corresponding to the configuration illustrated in FIG. 8B will be described:
FIG. 11A is a schematic configuration diagram of the gate wiring layer WLG in plan view, corresponding to the configuration illustrated in FIG. 8B;
FIG. 11B is a schematic configuration diagram of the first wiring layer WL1 in plan view, corresponding to the configuration illustrated in FIG. 8B; and
FIG. 11C is a schematic configuration diagram of the second wiring layer WL2 in plan view, corresponding to the configuration illustrated in FIG. 8B.

In FIG. 11A for the gate wiring layer WLG,
a gate 231g is the gate of the first overflow transistor 231; and
a gate 232g is the gate of the second overflow transistor 232.

In the present embodiment, the gate 231g and the gate 232g are made of P-type polysilicon.

In FIG. 11A,
the first charge accumulator FD1 is a diffusion layer that serves as both one of the source and drain of the first reset transistor 202 and one of the source and drain of the first overflow transistor 231;
the second charge accumulator FD2 is a diffusion layer that serves as both one of the source and drain of the second reset transistor 217 and one of the source and drain of the second overflow transistor 232;
a diffusion layer DL9 is a diffusion layer that is the other of the source and drain of the first overflow transistor 231; and
a diffusion layer DL10 is a diffusion layer that is the other of the source and drain of the second overflow transistor 232.

FIG. 11A also depicts contact plugs (hereinafter may simply be referred to as plugs) cpa3, cpp, cpq, and cpr.

As illustrated in FIG. 11B for the first wiring layer WL1, the first wiring layer WL1 includes a wire W1p and a wire W1r. FIG. 11B also depicts via plugs (hereinafter may simply be referred to as plugs) vp1p, vp1q, and vp1r.

As illustrated in FIG. 11C for the second wiring layer WL2, the second wiring layer WL2 includes a wire W2p, a wire W2q, and a wire W2r.

As understood from FIG. 11A for the gate wiring layer WLG, FIG. 11B for the first wiring layer WL1, and FIG. 11C for the second wiring layer WL2,
the plug cpa3 electrically connects the gate 231g and the wire W2a;
the plug cpp electrically connects the diffusion layer DL9 and the wire W1p;
the plug vp1p electrically connects the wire W1p and the wire W2p;
the plug cpq electrically connects the gate 232g and the wire W2q;
the plug vp1q electrically connects the wire W1d and the wire W2q;
the plug cpr electrically connects the diffusion layer DL10 and the wire W1r; and
the plug vp1r electrically connects the wire W1r and the wire W2r.

The wire W2p may be a wire that electrically connects the other of the source and drain of the first overflow transistor 231 and the first discharge line 235, or may be the first discharge line 235 itself. The wire W2r may be a wire that electrically connects the other of the source and drain of the second overflow transistor 232 and the second discharge line 236, or may be the second discharge line 236 itself.

Plan views of the MIM hierarchy MS, the third wiring layer WL3, the fourth wiring layer WL4, the fifth wiring layer WL5, the sixth wiring layer WL6, and the pixel electrode hierarchy ES corresponding to the configuration illustrated in FIG. 8B are omitted. Even in the case of adopting the configuration illustrated in FIG. 8B, these layers can be configured with reference to the configurations illustrated in FIGS. 10A to 10I corresponding to FIG. 7. Appropriate modifications may be made, such as adjusting the size of the first capacitor element 203 and the second capacitor element 213 in the MIM hierarchy MS.

Hereinafter, the non-limiting configuration of the imaging device 1 will be further described.

The imaging device 1 includes the semiconductor substrate 2 and the pixels 100. Each pixel 100 includes the first cell 100a, the second cell 100b, and an upper wiring layer. The sensitivity of the second cell 100b is lower than the sensitivity of the first cell 100a. The upper wiring layer is located above the semiconductor substrate 2. The upper wiring layer includes wires. The first cell 100a includes the first photoelectric converter 120, the first charge accumulator FD1, and a first wire. The first photoelectric converter 120 converts light into first signal charge. The first charge accumulator FD1 is located within the semiconductor substrate 2. The first charge accumulator FD1 accumulates the first signal charge. The first charge accumulator FD1 is electrically connected to the first node FDA. The first wire is located within the upper wiring layer. The first wire is electrically connected to the first node FDA. The second cell 100b includes the second photoelectric converter 130, the second charge accumulator FD2, and a second wire. The second photoelectric converter 130 converts light into second signal charge. The second charge accumulator FD2 is located within the semiconductor substrate 2. The second charge accumulator FD2 accumulates the second signal charge. The second charge accumulator FD2 is electrically connected to the second node FDB. The second wire is located within the upper wiring layer. The second wire is electrically connected to the second node FDB. Nodes to which the above-mentioned wires are respectively electrically connected are different from both the first node FDA and the second node FDB.

In the upper wiring layer, the shortest distance between the first wire and the wires is a first distance L1. In the upper wiring layer, the shortest distance between the second wire and the wires is a second distance L2. The first distance L1 is greater than the second distance L2. According to this configuration, it is easy to increase the first distance L1 and suppress the coupling between the wires and the first wire. Therefore, it is difficult for the capacitance value of the first node FDA to include the capacitance value of the parasitic capacitance caused by this coupling. This is advantageous from the perspective of increasing the conversion gain and reducing noise in the first cell 100a. Obtaining such advantageous effects in the first cell 100a, which has relatively high sensitivity, is suitable for realizing the high-quality imaging device 1. Furthermore, in this configuration, the second distance L2 is relatively small. Therefore, according to this configuration, the high-quality imaging device 1 can be realized while suppressing the size of the pixels 100.

Specifically, the first charge accumulator FD1 is a diffusion layer. The second charge accumulator FD2 is a diffusion layer. The first node FDA and the second node FDB are nodes that are different from each other.

Specifically, the first distance L1 and the second distance L2 are distances in a cross-section perpendicular to the thickness direction of the semiconductor substrate 2. The same applies to a third distance L3, a fifth distance L5, a sixth distance L6, a seventh distance L7 and an eighth distance L8, which will be described later.

In one example, the upper wiring layer is the first wiring layer WL1 illustrated in FIG. 10B. The first wire is the wire W1a. The first distance L1 is a shortest distance LA between the wire W1a and the wire W1c. The second wire is the wire W1d. The second distance L2 is a shortest distance LB between the wire W1d and the wire W1c.

In another example, the upper wiring layer is the third wiring layer WL3 illustrated in FIG. 10E. The first wire is the wire W3a. The first distance L1 is a shortest distance LC between the wire W3a and the first reset control line RSTiA. The second wire is the wire W3d. The second distance L2 is a shortest distance LD between the wire W3d and the first address control line SELiA.

Note that other examples may be adopted. For example, the upper wiring layer may be the gate wiring layer WLG illustrated in FIG. 10A, the second wiring layer WL2 illustrated in FIG. 10D, the fourth wiring layer WL4 illustrated in FIG. 10F, the fifth wiring layer WL5 illustrated in FIG. 10G, or the sixth wiring layer WL6 illustrated in FIG. 10H. The first wire may be the gate 205g, may be the wire W2a, may be the wire W4a, may be the wire W5a, or may be the wire W6a. The second wire may be the gate 215g, may be the wire W2d, may be the wire W4d, may be the wire W5d, or may be the wire W6d. The above-mentioned wires may include at least one selected from the group consisting of the gate 202g, gate 217g, gate 206g, gate 216g, gate 207g, wire W1c, wire W1e, wire W1f, wire W1g, wire W1h, wire W1i, wire W1j, wire W1k, wire W1p, wire W1r, wire W2c, wire W2e, wire W2f, wire W2g, wire W2h, wire W2i, wire W2j, wire W2k, wire W2p, wire W2q, wire W2r, wire W2s, wire W2t, wire W3c, wire W3e, wire W3h, wire W3i, wire W3j, wire W3s, wire W3t, first reset control line RSTia, second reset control line RSTiB, feedback control line FBi, first address control Line SELiA, second address control line SELiB, wire W4e, first vertical signal line 208ax, first vertical signal line 208ay, second vertical signal line 208bx, second vertical signal line 208by, first vertical signal line 208a, second vertical signal line 208b, first capacitance control line TPA, second capacitance control line TPB, wire W5e, power supply wire 209u, power supply wire 209x, power supply wire 209y, first feedback line 209a, second feedback line 209b, first discharge line 235, second discharge line 236, first transfer control line TRIA; and second transfer control line TRIB.

In the description of the configuration described later, specific examples of the upper wiring layer, the first wire, the second wire, the wires, and the like may also be provided. However, as with the description of the configuration described above, these specific examples are not particularly limited.

The expression “the sensitivity of the second cell 100b is lower than the sensitivity of the first cell 100a” may be rephrased as “the area in plan view of the second pixel electrode 103 in the second cell 100b is smaller than the area in plan view of the first pixel electrode 102 in the first cell 100a”. This expression may be rephrased as “the light collection area in plan view of the second microlens 113b in the second cell 100b is smaller than the light collection area in plan view of the first microlens 113a in the first cell 100a”.

The ratio L1/L2 of the first distance L1 to the second distance L2 is, for example, greater than or equal to 1.5 and less than or equal to 10. The ratio L1/L2 may be greater than or equal to 2 and less than or equal to 5.

The first distance L1 is, for example, greater than or equal to 100 nm and less than or equal to 1000 nm. The first distance L1 may be greater than or equal to 200 nm and less than or equal to 500 nm. The second distance L2 is, for example, greater than or equal to 50 nm and less than or equal to 1000 nm. The second distance L2 may be greater than or equal to 100 nm and less than or equal to 500 nm.

The pixel 100 includes a first capacitance wiring layer. The first capacitance wiring layer is located above the semiconductor substrate 2. The first capacitance wiring layer includes a first predetermined wire and a first specific wire. The first predetermined wire is electrically connected to the first node FDA. The first specific wire is electrically connected to the specific node RD. The first node FDA and the specific node RD are nodes that are different from each other. The first cell 100a includes the specific capacitor element 204. The specific capacitor element 204 includes the predetermined electrode 204a and the specific electrode 204b. The predetermined electrode 204a is electrically connected to the first node FDA. The specific electrode 204b is electrically connected to the first specific node RD. The predetermined electrode 204a includes a first predetermined wire. The specific electrode 204b includes a first specific wire. In this configuration, an electrode pair of the predetermined electrode 204a and the specific electrode 204b includes a wire pair of the first predetermined wire and the first specific wire. Therefore, utilizing the structural characteristics of the wire pair makes it suitable for realizing the specific capacitor element 204 with high accuracy and a small capacitance value. Realizing the specific capacitor element 204 with high accuracy may contribute to improving the accuracy of the capacitance value of the specific node RD. Note that, in this context, “high accuracy” means that the specific capacitor element 204 has a configuration suitable for minimizing variations in capacitance values caused by manufacturing variations of the imaging device 1 and the operating conditions of the imaging device 1. The capacitance value of the specific node RD is the capacitance value of the whole capacitance electrically connected to the specific node RD.

The pixel 100 includes a second capacitance wiring layer. The second capacitance wiring layer is located above the semiconductor substrate 2. The second capacitance wiring layer is located above or below the first capacitance wiring layer. The second capacitance wiring layer includes a second predetermined wire and a second specific wire. The second predetermined wire is electrically connected to the first node FDA. The second specific wire is electrically connected to the specific node RD. The predetermined electrode 204a includes the second predetermined wire. The specific electrode 204b includes the second specific wire. According to this configuration, it is easy to increase the ratio of the capacitance value of the specific capacitor element 204 to the capacitance value of the specific node RD and to improve the accuracy of the capacitance value of the specific node RD. Specifically, when the ratio of the component due to parasitic capacitance in the capacitance value of the specific node RD is high, it is difficult to obtain an accurate capacitance value of the specific node RD. However, according to this configuration, it is easy to secure the area of the predetermined electrode 204a and the specific electrode 204b and to secure the capacitance value of the specific capacitor element 204. Therefore, it is easy to increase the ratio of the capacitance value of the specific capacitor element 204 to the capacitance value of the specific node RD and to improve the accuracy of the capacitance value of the specific node RD.

With regard to the first capacitance wiring layer and the second capacitance wiring layer, the specific capacitor element 204 includes a dielectric located between the predetermined electrode 204a and the specific electrode 204b. The dielectric may include a portion of at least one insulating layer 3.

With regard to the first capacitance wiring layer and the second capacitance wiring layer, the first capacitance wiring layer may be the same as or different from the upper wiring layer. The first predetermined wire may be the same as or different from the first wire. The second capacitance wiring layer may be the same as or different from the upper wiring layer. The second predetermined wire may be the same as or different from the first wire.

With regard to the first capacitance wiring layer and the second capacitance wiring layer, in one example, the first capacitance wiring layer is the fifth wiring layer WL5 illustrated in FIG. 10G. The first predetermined wire is the wire W5a. The first specific wire is the wire W5b. The second capacitance wiring layer is the fourth wiring layer WL4 illustrated in FIG. 10F. The second predetermined wire is the wire W4a. The second specific wire is the wire W4b.

With regard to the first capacitance wiring layer and the second capacitance wiring layer, in another example, the first capacitance wiring layer is the fourth wiring layer WL4 illustrated in FIG. 10F. The first predetermined wire is the wire W4a. The first specific wire is the wire W4b. The second capacitance wiring layer is the fifth wiring layer WL5 illustrated in FIG. 10G. The second predetermined wire is the wire W5a. The second specific wire is the wire W5b.

In the first capacitance wiring layer, the shortest distance between the first predetermined wire and the first specific wire is the third distance L3. The third distance L3 is less than the first distance L1. In one example, the third distance L3 is a shortest distance LE between the wire W5a and the wire W5b in the fifth wiring layer WL5 illustrated in FIG. 10G. The third distance L3 may be less than the second distance L2.

The ratio L3/L1 of the third distance L3 to the first distance L1 is, for example, greater than or equal to 0.1 and less than or equal to 0.67. The ratio L3/L1 may be greater than or equal to 0.2 and less than or equal to 0.5. The ratio L3/L2 of the third distance L3 to the second distance L2 is, for example, greater than or equal to 0.1 and less than or equal to 0.67. The ratio L3/L2 may be greater than or equal to 0.2 and less than or equal to 0.5.

The third distance L3 is, for example, greater than or equal to 100 nm and less than or equal to 1000 nm. The third distance L3 may be greater than or equal to 200 nm and less than or equal to 500 nm.

As illustrated in FIG. 10G, in one example, in a cross-section that crosses the first capacitance wiring layer and that is perpendicular to the thickness direction of the semiconductor substrate 2, there is a straight line SL that passes through a first portion po1 of the first specific wire, a predetermined portion pp of the first predetermined wire, and a second portion po2 of the first specific wire in this order. According to this configuration, it is easy to increase the ratio of the capacitance value of the specific capacitor element 204 to the capacitance value of the specific node RD and to improve the accuracy of the capacitance value of the specific node RD. Specifically, when the ratio of the component due to parasitic capacitance in the capacitance value of the specific node RD is high, it is difficult to obtain an accurate capacitance value of the specific node RD. However, according to this configuration, it is easy to secure the capacitance value of the specific capacitor element 204. Therefore, it is easy to increase the ratio of the capacitance value of the specific capacitor element 204 to the capacitance value of the specific node RD and to improve the accuracy of the capacitance value of the specific node RD.

Specifically, even if the predetermined portion pp is set at any position on the first predetermined wire in a cross-section that crosses the first capacitance wiring layer and that is perpendicular to the thickness direction of the semiconductor substrate 2, there may be the straight line SL passing through the first portion po1, the predetermined portion pp, and the second portion po2 in this order. According to this configuration, it is easy to increase the ratio of the capacitance value of the specific capacitor element 204 to the capacitance value of the specific node RD and to improve the accuracy of the capacitance value of the specific node RD.

The first cell 100a includes the first amplifier transistor 205, which generates a first electric signal according to the potential of the first charge accumulator FD1. The first electric signal is negatively fed back to the first charge accumulator FD1 through the specific capacitor element 204. According to this configuration, the specific capacitor element 204 can be used for negative feedback of the first electric signal.

The imaging device 1 includes the power supply wire 209u electrically connected to the power supply node VR, which is different from the first node FDA, the second node FDB, and the specific node RD. The first cell 100a includes the first amplifier transistor 205. The first amplifier transistor 205 generates a first electric signal according to the potential of the first charge accumulator FD1. The power supply potential VDD is supplied to the first amplifier transistor 205 through the power supply wire 209u. In the example illustrated in FIG. 10G, in the first capacitance wiring layer, the first specific wire is located between the power supply wire 209u and the first predetermined wire. According to this configuration, the first specific wire may act as a shield for suppressing coupling between the power supply wire 209u and the first predetermined wire.

The expression “in the first capacitance wiring layer, the first specific wire is located between the power supply wire 209u and the first predetermined wire” in the above-mentioned configuration will be described. This expression means that, in a cross-section that crosses the first capacitance wiring layer and that is perpendicular to the thickness direction of the semiconductor substrate 2, there is a straight line that passes through the power supply wire 209u, the first specific wire, and the first predetermined wire in this order.

The first electric signal is negatively fed back to the first charge accumulator FD1 through the specific capacitor element 204. The potential of the first electric signal negatively fed back is applied to the power supply wire 209u. According to this configuration, even if a potential fluctuation occurs in the power supply wire 209u due to the negative feedback of the first electric signal, its impact on the capacitance of the first node FDA can be suppressed by the shielding action mentioned above. This is suitable for reducing noise in the first cell 100a and realizing the high-quality imaging device 1.

As mentioned earlier, in the first capacitance wiring layer, the shortest distance between the first predetermined wire and the first specific wire is the third distance L3. The first cell 100a includes the first capacitor element 203. The first capacitor element 203 has the electrode 203a and the electrode 203b. The electrode 203a is electrically connected to the specific node RD. The electrode 203b is electrically isolated from the electrode 203a. The electrode 203a is located between the electrode 203b and the semiconductor substrate 2. The shortest distance between the electrode 203a and the semiconductor substrate 2 is a fourth distance L4. The third distance L3 is less than the fourth distance L4. According to this configuration, it is easy to increase the ratio of the capacitance value of the specific capacitor element 204 to the capacitance value of the specific node RD and to improve the accuracy of the capacitance value of the specific node RD. Specifically, in the first cell 100a according to this configuration, there may be a parasitic capacitance between the electrode 203a and the semiconductor substrate 2. However, according to this configuration, it is easy to increase the ratio of the capacitance value of the specific capacitor element 204 to the capacitance value of this parasitic capacitance. Therefore, it is easy to increase the ratio of the capacitance value of the specific capacitor element 204 to the capacitance value of the specific node RD and to improve the accuracy of the capacitance value of the specific node RD.

The ratio L3/L4 of the third distance L3 to the fourth distance L4 is, for example, greater than or equal to 0.1 and less than or equal to 0.67. The ratio L3/L4 may be greater than or equal to 0.2 and less than or equal to 0.5.

The fourth distance L4 is, for example, greater than or equal to 100 nm and less than or equal to 1000 nm. The fourth distance L4 may be greater than or equal to 200 nm and less than or equal to 500 nm.

In one example, the third distance L3 is the shortest distance LE between the wire W5a and the wire W5b in the fifth wiring layer WL5 illustrated in FIG. 10G. The fourth distance L4 is a shortest distance LF between the protrusion 203p and the semiconductor substrate 2 illustrated in FIG. 3. The fourth distance L4 is specifically a distance in a direction parallel to the thickness direction of the semiconductor substrate 2.

The first cell 100a includes the first capacitor element 203 electrically connected to the specific node RD. The first capacitor element 203 is a MIM capacitor element. This configuration is suitable for realizing the first capacitor element 203 with a large capacitance value. The first capacitor element 203 may be a metal-oxide-semiconductor (MOS) capacitor element. This also allows the realization of the first capacitor element 203 with a large capacitance value.

The second cell 100b includes the second capacitor element 213 electrically connected to the second node FDB. The second capacitor element 213 is a MIM capacitor element. This configuration is suitable for realizing the second capacitor element 213 with a large capacitance value. The second capacitor element 213 may be a MOS capacitor element. This also allows the realization of the second capacitor element 213 with a large capacitance value.

The capacitance value of the specific capacitor element 204 is small compared to the capacitance value of the first capacitor element 203. The ratio of the capacitance value of the specific capacitor element 204 to the capacitance value of the first capacitor element 203 is, for example, greater than or equal to 5% and less than or equal to 20%. This ratio may be greater than or equal to 5% and less than or equal to 15%.

The capacitance value of the specific capacitor element 204 is small compared to the capacitance value of the second capacitor element 213. The ratio of the capacitance value of the specific capacitor element 204 to the capacitance value of the second capacitor element 213 is, for example, greater than or equal to 5% and less than or equal to 20%. This ratio may be greater than or equal to 5% and less than or equal to 15%.

In one example, the specific capacitor element 204 is configured across wiring layers. The wiring layers include, for example, the fourth wiring layer WL4 and the fifth wiring layer WL5. Additionally, the specific capacitor element 204 is configured across insulating layers 3. The insulating layers 3 include, for example, the insulating layer 3c and the insulating layer 3d. In contrast, the first capacitor element 203 and the second capacitor element 213 are contained within a single insulating layer 3. The single insulating layer 3 is, for example, the insulating layer 3a. Here, “across a first element and a second element” means so as to include at least a portion of the first element and at least a portion of the second element.

In one example, the above-mentioned wires are all wires in the upper wiring layer excluding all wires electrically connected to the specific node RD. In another example, the above-mentioned wires are all wires in the upper wiring layer. In this context, the number of “all wires electrically connected to the specific node RD” may be one or plural.

In a cross-section that crosses the upper wiring layer and that is perpendicular to the thickness direction of the semiconductor substrate 2, an area S1 of the first wire is less than an area S2 of the second wire. According to this configuration, it is easy to reduce the area S1 of the first wire and suppress the coupling between the wires and the first wire. Therefore, it is difficult for the capacitance value of the first node FDA to include the capacitance value of the parasitic capacitance caused by this coupling. This is advantageous from the perspective of increasing the conversion gain and reducing noise in the first cell 100a. Obtaining such advantageous effects in the first cell 100a, which has relatively high sensitivity, is suitable for realizing the high-quality imaging device 1.

The ratio S1/S2 of the area S1 to the area S2 is, for example, greater than or equal to 10% and less than or equal to 90%. The ratio S1/S2 may be greater than or equal to 30% and less than or equal to 50%.

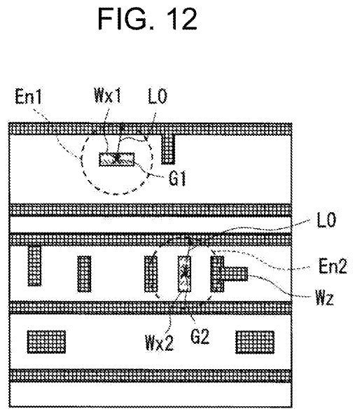

FIG. 12 is a schematic plan view for describing the relationship between area ratios. The concept of the area ratios illustrated in FIG. 12 is applicable to schematic configuration diagrams for each wiring layer in plan views illustrated in FIGS. 10A to 10H and FIGS. 11A to 11C.

In the imaging device 1, pixels 100 are arranged at a predetermined pitch L0. As schematically illustrated in FIG. 12, the geometric center of a first wire Wx1 is defined as a first central point G1 in a cross-section that crosses the upper wiring layer and that is perpendicular to the thickness direction of the semiconductor substrate 2. In this cross-section, the geometric center of a second wire Wx2 is defined as a second central point G2. In this cross-section, a region surrounded by a circle centered on the first central point G1 and having a radius of ⅛ of the pitch L0 is defined as a first encircling region En1. In this cross-section, a region surrounded by a circle centered on the second central point G2 and having a radius of ⅛ of the pitch L0 is defined as a second encircling region En2. In this cross-section, the ratio of the area occupied by wires Wz in the first encircling region En1 is defined as a first area ratio R1. In this cross-section, the ratio of the area occupied by the wires Wz in the second encircling region En2 is defined as a second area ratio R2. At this time, the first area ratio R1 is less than the second area ratio R2. According to this configuration, it is easy to reduce the first area ratio R1 and suppress the coupling between the wires Wz and the first wire. Therefore, it is difficult for the capacitance value of the first node FDA to include the capacitance value of the parasitic capacitance caused by this coupling. This is advantageous from the perspective of increasing the conversion gain and reducing noise in the first cell 100a. Obtaining such advantageous effects in the first cell 100a, which has relatively high sensitivity, is suitable for realizing the high-quality imaging device 1.

Note that, in a more detailed expression, the first area ratio R1 is the ratio of the area of the portions of the wires Wz located within the first encircling region En1 to the area of the first encircling region En1. The second area ratio R2 is the ratio of the area of the portions of the wires Wz located within the second encircling region En2 to the area of the second encircling region En2.

The pitch L0 will be described with reference to FIGS. 4 and 5. The pitch L0 is one based on any one of definitions 1 to 12 below.

Definition 1: The pitch L0 is a pitch Pm1x at which the first microlenses 113a are aligned in the row direction.

Definition 2: The pitch L0 is a pitch Pm1y at which the first microlenses 113a are aligned in the column direction.

Definition 3: The pitch L0 is the arithmetic mean of the pitch Pm1x and the pitch Pm1y.

Definition 4: The pitch L0 is a pitch Pm2x at which the second microlenses 113b are aligned in the row direction.

Definition 5: The pitch L0 is a pitch Pm2y at which the second microlenses 113b are aligned in the column direction.

Definition 6: The pitch L0 is the arithmetic mean of the pitch Pm2x and the pitch Pm2y.

Definition 7: The pitch L0 is a pitch Pe1x at which the first pixel electrodes 102 are aligned in the row direction.

Definition 8: The pitch L0 is a pitch Pe1y at which the first pixel electrodes 102 are aligned in the column direction.

Definition 9: The pitch L0 is the arithmetic mean of the pitch Pe1x and the pitch Pe1y.

Definition 10: The pitch L0 is a pitch Pe2x at which the second pixel electrodes 103 are aligned in the row direction.

Definition 11: The pitch L0 is a pitch Pe2y at which the second pixel electrodes 103 are aligned in the column direction.

Definition 12: The pitch L0 is the arithmetic mean of the pitch Pe2x and the pitch Pe2y.

In the present embodiment, if it can be said that “the first area ratio R1 is less than the second area ratio R2” based on any one of definitions 1 to 12, it is handled that “the first area ratio R1 is less than the second area ratio R2”.

The ratio R1/R2 of the first area ratio R1 to the second area ratio R2 is, for example, greater than or equal to 10% and less than or equal to 90%. The ratio R1/R2 may be greater than or equal to 30% and less than or equal to 50%.

The first area ratio R1 is, for example, greater than or equal to 10% and less than or equal to 70%. The first area ratio R1 may be greater than or equal to 20% and less than or equal to 50%. The second area ratio R2 is, for example, greater than or equal to 10% and less than or equal to 70%. The second area ratio R2 may be greater than or equal to 20% and less than or equal to 50%.

The upper wiring layer includes a first signal wire and a second signal wire. The first cell 100a includes a first transistor. The first transistor includes a first source, a first drain, and a first gate. The first source or the first drain is the first charge accumulator FD1. A first control signal is supplied to the first gate through the first signal wire. The second cell 100b includes a second transistor. The second transistor includes a second source, a second drain, and a second gate. The second source or the second drain is the second charge accumulator FD2. A second control signal is supplied to the second gate through the second signal wire.

In the upper wiring layer, the shortest distance between the first wire and the first signal wire is the fifth distance L5. In the upper wiring layer, the shortest distance between the second wire and the second signal wire is the sixth distance L6. The fifth distance L5 is greater than the sixth distance L6. According to this configuration, it is easy to increase the fifth distance L5 and suppress the coupling between the first signal wire and the first wire. Therefore, it is difficult for the capacitance value of the first node FDA to include the capacitance value of the parasitic capacitance caused by this coupling. This is advantageous from the perspective of increasing the conversion gain and reducing noise in the first cell 100a. Obtaining such advantageous effects in the first cell 100a, which has relatively high sensitivity, is suitable for realizing the high-quality imaging device 1. Furthermore, in this configuration, the sixth distance L6 is relatively small. Therefore, according to this configuration, the high-quality imaging device 1 can be realized while suppressing the size of the pixels 100.

In one example, the first transistor is the first reset transistor 202. The first control signal is a first reset control signal. The second transistor is the second reset transistor 217. The second control signal is a second reset control signal. The upper wiring layer is the first wiring layer WL1 illustrated in FIG. 10B. The first wire is the wire W1a. The first signal wire is the wire W1c. The fifth distance L5 is the shortest distance LA between the wire W1a and the wire W1c. The second wire is the wire W1d. The second signal wire is the wire W1f. The sixth distance L6 is a shortest distance LG between the wire W1d and the wire W1f.

Note that other examples may be adopted. For example, the first transistor may be the first transfer transistor 245. The first control signal may be the first transfer control signal. The second transistor may be the second transfer transistor 246. The second control signal may be the second transfer control signal. The first signal wire may be another wire electrically connected to the gate of the first transistor. The upper wiring layer may be a wiring layer including this other wire. The second signal wire may be another wire electrically connected to the gate of the second transistor. The upper wiring layer may be a wiring layer including this other wire.

The ratio L5/L6 of the fifth distance L5 to the sixth distance L6 is, for example, greater than or equal to 1.5 and less than or equal to 10. The ratio L5/L6 may be greater than or equal to 2 and less than or equal to 5.

The fifth distance L5 is, for example, greater than or equal to 100 nm and less than or equal to 1000 nm. The fifth distance L5 may be greater than or equal to 200 nm and less than or equal to 500 nm. The sixth distance L6 is, for example, greater than or equal to 50 nm and less than or equal to 1000 nm. The sixth distance L6 may be greater than or equal to 100 nm and less than or equal to 500 nm.

The first cell 100a includes a first plug and the first capacitor element 203. The first plug is electrically connected to the first node FDA. The first capacitor element 203 has the electrode 203a and the electrode 203b. The second cell 100b includes a second plug and the second capacitor element 213. The second plug is electrically connected to the second node FDB. The second capacitor element 213 has the electrode 213a and the electrode 213b. In a cross-section that crosses the first capacitor element 203 and that is perpendicular to the thickness direction of the semiconductor substrate 2, the shortest distance between the first plug and the electrode 203b is the seventh distance L7. In this cross-section, the shortest distance between the second plug and the electrode 213b is the eighth distance L8. The seventh distance L7 is greater than the eighth distance L8. According to this configuration, it is easy to increase the seventh distance L7 and suppress the coupling between the electrode 203b and the first plug. Therefore, it is difficult for the capacitance value of the first node FDA to include the capacitance value of the parasitic capacitance caused by this coupling. This is advantageous from the perspective of increasing the conversion gain and reducing noise in the first cell 100a. Obtaining such advantageous effects in the first cell 100a, which has relatively high sensitivity, is suitable for realizing the high-quality imaging device 1. Furthermore, in this configuration, the eighth distance L8 is relatively small. Therefore, according to this configuration, the high-quality imaging device 1 can be realized while suppressing the size of the pixels 100.

In one example, the first plug is the plug vp1a illustrated in FIG. 10C. The second plug is the plug vp1d. The seventh distance L7 is a shortest distance LH between the plug vp1a and the electrode 203b. The eighth distance L8 is a shortest distance L1 between the plug vp1d and the electrode 213b.

The ratio L7/L8 of the seventh distance L7 to the eighth distance L8 is, for example, greater than or equal to 1.5 and less than or equal to 10. The ratio L7/L8 may be greater than or equal to 2 and less than or equal to 5.

The seventh distance L7 is, for example, greater than or equal to 100 nm and less than or equal to 1000 nm. The seventh distance L7 may be greater than or equal to 200 nm and less than or equal to 500 nm. The eighth distance L8 is, for example, greater than or equal to 50 nm and less than or equal to 1000 nm. The eighth distance L8 may be greater than or equal to 100 nm and less than or equal to 500 nm.

The first cell 100a includes a first transistor. The second cell 100b includes a second transistor. One of the source and drain of the first transistor is the first charge accumulator FD1. One of the source and drain of the second transistor is the second charge accumulator FD2. The first transistor and the electrode 203a are electrically connected. The second transistor and the electrode 213a are electrically connected. In one example, as illustrated in FIG. 2 and the like, the first transistor is the first reset transistor 202. The second transistor is the second reset transistor 217.

As illustrated in FIG. 10C, in a cross-section that crosses the first capacitor element 203 and that is perpendicular to the thickness direction of the semiconductor substrate 2, the first capacitor element 203 is provided with a recess 203x that opens toward a predetermined direction Dx. In this cross-section, the first plug is located within the recess 203x. In the upper wiring layer, the first signal wire is located on the predetermined direction Dx side relative to the first wire. According to this configuration, it is easier to secure both the fifth distance L5 and the seventh distance L7 compared to the case where the recess 203x is provided and the first plug is not placed within the recess 203x. This is advantageous from the perspective of increasing the conversion gain and reducing noise in the first cell 100a. Obtaining such advantageous effects in the first cell 100a, which has relatively high sensitivity, is suitable for realizing the high-quality imaging device 1. In one example, the upper wiring layer is the third wiring layer WL3 illustrated in FIG. 10E. The first wire is the wire W3a. The first signal wire is the first reset control line RSTiA. The fifth distance L5 is the shortest distance LC between the wire W3a and the first reset control line RSTiA. The seventh distance L7 is the shortest distance LH between the plug vp1a and the electrode 203b, illustrated in FIG. 10C.

The ratio L7/L5 of the seventh distance L7 to the fifth distance L5 is, for example, greater than or equal to 0.5 and less than or equal to 2. If the fifth distance L5 and the seventh distance L7 are set to close values to this extent, it becomes less likely that the fifth distance L5 or the seventh distance L7 will become extremely small. This is suitable for realizing the high-quality imaging device 1. The ratio L7/L5 may be greater than or equal to 0.8 and less than or equal to 1.25.

The fifth distance L5 may be greater than the seventh distance L7. The fifth distance L5 may be less than the seventh distance L7. The fifth distance L5 and the seventh distance L7 may be the same.

The imaging device 1 includes an intermediate wire. The intermediate wire electrically connects the first plug and the first wire. In a plan view, the intermediate wire extends from a position within the recess 203x to a position on the predetermined direction Dx side relative to the recess 203x. According to the intermediate wire, it is easy to achieve the above-mentioned positional relationship among the recess 203x, the first plug, the first wire, and the first signal wire. In one example, the intermediate wire is the wire W3c illustrated in FIG. 10E. In this example, in the upper wiring layer, the first signal wire and the intermediate wire are electrically connected.

Although the imaging device according to the present disclosure has been described above based on an embodiment that achieves low noise and a wide dynamic range, the present disclosure is not limited to the embodiment and modifications thereof. Various modifications conceived by those skilled in the art, implemented in the embodiment and its modifications, as long as they do not depart from the gist of the present disclosure, as well as other embodiments constructed by combining some components of the embodiment and their modifications, are within the scope of the present disclosure.

The imaging device of the present disclosure is useful for, for example, image sensors, digital cameras, and the like. The imaging device of the present disclosure can be used in medical cameras, robotic cameras, security cameras, cameras mounted and used in vehicles, and the like.

What is claimed is:

1. An imaging device comprising:
a semiconductor substrate; and
a pixel including a first cell, a second cell that is less sensitive than the first cell, and an upper wiring layer located above the semiconductor substrate and including wires,
the first cell including:
a first photoelectric converter that converts light into first signal charge;
a first charge accumulator located within the semiconductor substrate, accumulating the first signal charge, and electrically connected to a first node; and
a first wire located within the upper wiring layer and electrically connected to the first node,
the second cell including:
a second photoelectric converter that converts light into second signal charge;
a second charge accumulator located within the semiconductor substrate, accumulating the second signal charge, and electrically connected to a second node; and
a second wire located within the upper wiring layer and electrically connected to the second node,
wherein nodes to which the wires are respectively electrically connected are different from both the first node and the second node, and
in the upper wiring layer,
a shortest distance between the first wire and the wires is greater than a shortest distance between the second wire and the wires.

2. The imaging device according to claim 1, wherein:
the pixel includes a first capacitance wiring layer located above the semiconductor substrate,
the first capacitance wiring layer includes:
a first predetermined wire electrically connected to the first node; and
a first specific wire electrically connected to a specific node different from the first node,
the first cell includes a specific capacitor element; and
the specific capacitor element includes the first predetermined wire and the first specific wire.

3. The imaging device according to claim 2, wherein:
the pixel includes a second capacitance wiring layer located above the semiconductor substrate and above or below the first capacitance wiring layer,
the second capacitance wiring layer includes:
a second predetermined wire electrically connected to the first node; and
a second specific wire electrically connected to the specific node; and
the specific capacitor element includes the second predetermined wire and the second specific wire.

4. The imaging device according to claim 2, wherein:
in a cross-section that crosses the first capacitance wiring layer and that is perpendicular to a thickness direction of the semiconductor substrate, there is a straight line that passes through a first portion of the first specific wire, a predetermined portion of the first predetermined wire, and a second portion of the first specific wire in this order.

5. The imaging device according to claim 2, wherein:
the first cell includes a first amplifier transistor that generates a first electric signal according to a potential of the first charge accumulator; and
the first electric signal is negatively fed back to the first charge accumulator through the specific capacitor element.

6. The imaging device according to claim 2, comprising:
a power supply wire electrically connected to a power supply node different from the first node, the second node, and the specific node,
wherein the first cell includes a first amplifier transistor that generates a first electric signal according to a potential of the first charge accumulator and that is supplied with a power supply potential through the power supply wire, and
in the first capacitance wiring layer, the first specific wire is located between the power supply wire and the first predetermined wire.

7. The imaging device according to claim 6, wherein:
the first electric signal is negatively fed back to the first charge accumulator through the specific capacitor element; and
a potential of the first electric signal negatively fed back is applied to the power supply wire.

8. The imaging device according to claim 2, wherein:
the first cell includes a first capacitor element;
the first capacitor element includes a first electrode electrically connected to the specific node and a second electrode electrically isolated from the first electrode;
the first electrode is located between the second electrode and the semiconductor substrate; and
a shortest distance between the first predetermined wire and the first specific wire in the first capacitance wiring layer is less than a shortest distance between the first electrode and the semiconductor substrate.

9. The imaging device according to claim 2, wherein:
the first cell includes a metal-insulator-metal (MIM) capacitor element or a metal-oxide-semiconductor (MOS) capacitor element electrically connected to the specific node.

10. The imaging device according to claim 2, wherein:
the wires are all wires in the upper wiring layer excluding all wires electrically connected to the specific node.

11. The imaging device according to claim 1, wherein:
the wires are all wires in the upper wiring layer.

12. An imaging device comprising:
a semiconductor substrate; and
a pixel including a first cell, a second cell that is less sensitive than the first cell, and an upper wiring layer located above the semiconductor substrate and including a first signal wire and a second signal wire,
the first cell including:
a first photoelectric converter that converts light into first signal charge;
a first charge accumulator located within the semiconductor substrate, accumulating the first signal charge, and electrically connected to a first node;
a first wire located within the upper wiring layer and electrically connected to the first node; and
a first transistor including a first source or a first drain that is the first charge accumulator and a first gate to which a first control signal is supplied through the first signal wire,
the second cell including:
a second photoelectric converter that converts light into second signal charge;
a second charge accumulator located within the semiconductor substrate, accumulating the second signal charge, and electrically connected to a second node;
a second wire located within the upper wiring layer and electrically connected to the second node; and
a second transistor including a second source or a second drain that is the second charge accumulator and a second gate to which a second control signal is supplied through the second signal wire, and
in the upper wiring layer,
a shortest distance between the first wire and the first signal wire is greater than a shortest distance between the second wire and the second signal wire.

13. An imaging device comprising:
a semiconductor substrate; and
a pixel including a first cell, a second cell that is less sensitive than the first cell, and an upper wiring layer located above the semiconductor substrate and including wires,
the first cell including:
a first photoelectric converter that converts light into first signal charge;
a first charge accumulator located within the semiconductor substrate, accumulating the first signal charge, and electrically connected to a first node; and
a first wire located within the upper wiring layer and electrically connected to the first node;
the second cell including:
a second photoelectric converter that converts light into second signal charge;
a second charge accumulator located within the semiconductor substrate, accumulating the second signal charge, and electrically connected to a second node; and
a second wire located within the upper wiring layer and electrically connected to the second node,
wherein nodes to which the wires are respectively electrically connected are different from both the first node and the second node, and
in a cross-section that crosses the upper wiring layer and that is perpendicular to a thickness direction of the semiconductor substrate, an area of the first wire is less than an area of the second wire.

14. An imaging device comprising:
a semiconductor substrate; and
pixels arranged at a predetermined pitch,
the pixels including at least one pixel,
the at least one pixel including a first cell, a second cell that is less sensitive than the first cell, and an upper wiring layer located above the semiconductor substrate and including wires,
the first cell including:
a first photoelectric converter that converts light into first signal charge;
a first charge accumulator located within the semiconductor substrate, accumulating the first signal charge, and electrically connected to a first node; and
a first wire located within the upper wiring layer and electrically connected to the first node,
the second cell including:
a second photoelectric converter that converts light into second signal charge;
a second charge accumulator located within the semiconductor substrate, accumulating the second signal charge, and electrically connected to a second node; and
a second wire located within the upper wiring layer and electrically connected to the second node,
wherein nodes to which the wires are respectively electrically connected are different from both the first node and the second node, and
in a cross-section that crosses the upper wiring layer and that is perpendicular to a thickness direction of the semiconductor substrate,
if a geometric center of the first wire is defined as a first central point,
a geometric center of the second wire is defined as a second central point,
a region surrounded by a circle centered on the first central point and having a radius of ⅛ of the pitch is defined as a first encircling region,
a region surrounded by a circle centered on the second central point and having a radius of ⅛ of the pitch is defined as a second encircling region,
a ratio of an area occupied by the wires in the first encircling region is defined as a first area ratio, and
a ratio of an area occupied by the wires in the second encircling region is defined as a second area ratio,
then, the first area ratio is less than the second area ratio.

15. An imaging device comprising:
a semiconductor substrate; and
a pixel including a first cell and a second cell that is less sensitive than the first cell,
the first cell including:
a first photoelectric converter that converts light into first signal charge;
a first charge accumulator located within the semiconductor substrate, accumulating the first signal charge, and electrically connected to a first node;
a first plug electrically connected to the first node; and
a first capacitor element having a first electrode and a second electrode,
the second cell including:
a second photoelectric converter that converts light into second signal charge;
a second charge accumulator located within the semiconductor substrate, accumulating the second signal charge, and electrically connected to a second node;
a second plug electrically connected to the second node; and
a second capacitor element having a third electrode and a fourth electrode, and
in a cross-section that crosses the first capacitor element and that is perpendicular to a thickness direction of the semiconductor substrate,
a shortest distance between the first plug and the second electrode is greater than a shortest distance between the second plug and the fourth electrode.

16. The imaging device according to claim 15, wherein:
the first cell includes a first transistor;
the second cell includes a second transistor;
one of a source and a drain of the first transistor is the first charge accumulator;
one of a source and a drain of the second transistor is the second charge accumulator;
the first transistor and the first electrode are electrically connected; and
the second transistor and the third electrode are electrically connected.

17. An imaging device comprising:
a semiconductor substrate and a pixel,
the pixel including:
an upper wiring layer located above the semiconductor substrate and including a first signal wire;
a first photoelectric converter that converts light into first signal charge;
a first charge accumulator located within the semiconductor substrate, accumulating the first signal charge, and electrically connected to a first node;
a first wire located within the upper wiring layer and electrically connected to the first node;
a first plug electrically connected to the first node;
a first capacitor element having a first electrode and a second electrode; and
a first transistor including a first source or a first drain that is the first charge accumulator and a first gate to which a first control signal is supplied through the first signal wire,
wherein, in a cross-section that crosses the first capacitor element and that is perpendicular to a thickness direction of the semiconductor substrate, the first plug is located within a recess that is provided in the first capacitor element and that opens toward a predetermined direction, and
in the upper wiring layer, the first signal wire is located on the predetermined direction side relative to the first wire.

18. The imaging device according to claim 17, comprising:
an intermediate wire that electrically connects the first plug and the first wire,
wherein, in a plan view, the intermediate wire extends from a position within the recess to a position on the predetermined direction side relative to the recess.

19. The imaging device according to claim 17, wherein a ratio of a shortest distance between the first plug and the second electrode in the cross-section crossing the first capacitor element and perpendicular to the thickness direction of the semiconductor substrate to a shortest distance between the first wire and the first signal wire in the upper wiring layer is greater than or equal to 0.5 and less than or equal to 2.

20. The imaging device according to claim 17, wherein:
the pixel includes a first cell and a second cell that is less sensitive than the first cell, and
the first cell includes:
the first photoelectric converter;
the first charge accumulator;
the first wire;
the first plug;
the first capacitor element; and
the first transistor.

21. An imaging device comprising:
a semiconductor substrate; and
a pixel including a first cell, a second cell that is less sensitive than the first cell, and an upper wiring layer located above the semiconductor substrate and including wires,
the first cell including:
a first photoelectric converter that converts light into first signal charge;
a first charge accumulator located within the semiconductor substrate, accumulating the first signal charge, and electrically connected to a first node; and
a first wire located within the upper wiring layer and electrically connected to the first node,
the second cell including:
a second photoelectric converter that converts light into second signal charge;
a second charge accumulator located within the semiconductor substrate, accumulating the second signal charge, and electrically connected to a second node; and
a second wire located within the upper wiring layer and electrically connected to the second node,
wherein nodes to which the wires are respectively electrically connected are different from both the first node and the second node, and
in the upper wiring layer,
a shortest distance between the first wire and, among the wires, a wire that does not form a capacitance with the first wire is greater than a shortest distance between the second wire and, among the wires, a wire that does not form a capacitance with the second wire.
